(19) United States
(12) Patent Application Publication
(10) Pub. No.: US 2010/0188081 A1
(43) Pub. Date: Jul. 29, 2010

(54) Method and Device for Measuring Magnetic Fields

(75) Inventor: Roland Lammegger, Graz (AT)

Correspondence Address: CHALKER FLORES, LLP, 2711 LBJ FRWY, Suite 1036, DALLAS, TX, 75234, US

(73) Assignees: TECHNISCHE UNIVERSITAT GRAZ, Graz (AT); FORSCHUNGSHOLDING TU GRAZ GMBH, Graz (AT)

(21) Appl. No.: 12/664,782

(22) PCT Filed: Jun. 12, 2008
(86) PCT No.: PCT/AT2008/000208

§ 371 Date: Dec. 15, 2009

(30) Foreign Application Priority Data
Jun. 15, 2007 (AT) A 932/2007

(51) Int. Cl. G01R 33/26; G01R 33/032

(52) U.S. Cl. 324/304

(57) ABSTRACT

The invention relates to a method which makes use of the Zeeman effect for measuring magnetic fields, by way of dark resonances. According to said method, a measuring cell (14) is exposed to the magnetic field (B) to be measured and contains the atoms of a measuring medium in a buffer gas, a radiation source (11) being provided for exciting the atoms by radiation and being connected to the modulation frequency generator and emitting electromagnetic radiation with different frequencies. A frequency detector (17) is mounted downstream of the measuring cell (14) and comprises a control loop (18) for the frequency tuning to a dark resonance frequency. The invention is characterized in that at least one modulator (22) for modulating a comparatively high first modulation frequency with a lower second modulation frequency, thereby producing a double sideband structure, is arranged downstream of the modulation frequency generator (24) to couple a plurality of dark resonances using the electromagnetic radiation (12) modulated therewith, substantially only one frequency being detected according to the magnetic field-dependent frequency shift.

The invention relates to a method and a device for measuring magnetic fields based on the magnetic field dependence of the energy level on atomic or molecular quantum systems (Zeeman effect) using dark resonance according to the introductory passages of the independent claims.

Dark resonance is a resonance phenomenon caused by a quantum mechanical interference effect in atomic or molecular systems. A quantum mechanical system excited with resonant electromagnetic radiation is shifted into a destructive superposition state of the wave functions of the ground states of the quantum system. In this state, the quantum mechanical system is decoupled from the excitation process of the electromagnetic radiation. A medium consisting of such systems becomes transparent as a consequence of this phenomenon. The diminished absorption results in a diminished fluorescent radiation for reasons of energy conservation. The medium appears darker, thus resulting in the name dark resonance. The observation of this effect requires the observance of certain conditions with regard to the electronic structure (so-called Λ-system). The line widths of the CPT resonances (CPT=coherent population trapping) can be very small, making these resonances suitable for precision measurements (e.g., CPT atomic clock, CPT magnetometer).

In the simplest case, CPT dark states or dark resonances can be observed in a quantum mechanical system consisting of three energy levels. The precondition for observing CPT dark resonances is the mutual coupling of the three energy levels by means of an electromagnetic radiation field (e.g., by several laser frequencies). This coupling can be produced in the simplest case by exciting two of the three possible (energy) transitions of the three-level system. The radiation field must then consist of two (spectral) components of varying frequency (bichromatic electromagnetic field), i.e., a bichromatic electromagnetic field is used.

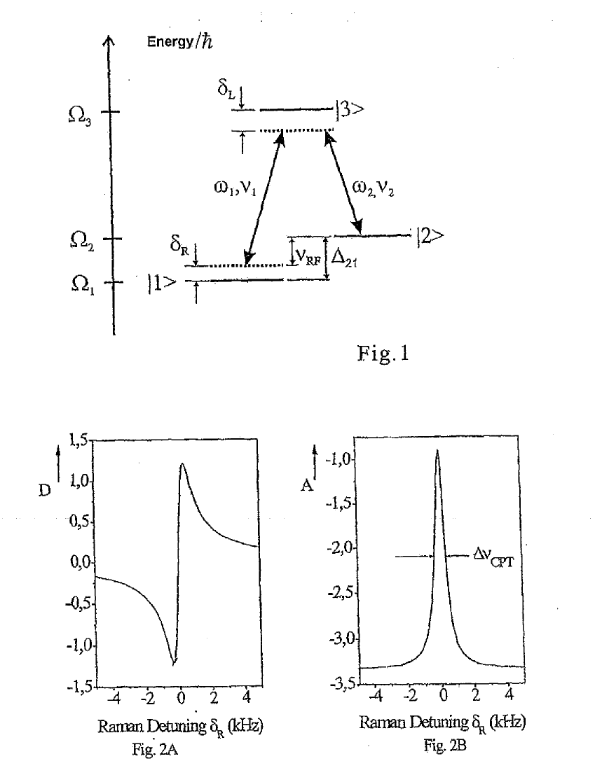

FIG. 1 presents a graphic depiction of this situation. The energy levels are very generally described by the quantum mechanical states |1>, |2> and |3>. This type of level designation is initially selected at random. In a specific quantum mechanical system (e.g., the hyperfine structure of an alkali metal atomic vapor that can also be present according to the invention), it can be replaced by the spectroscopic notation of the respective energy level. The designation of the energy level actually refers to the corresponding quantum mechanical wave function. Knowledge about these wave functions may be gained from the theory of atoms (molecules). This information is known for all atomic levels mentioned herein.

On FIG. 1, the two frequency components of a bichromatic electromagnetic field (e.g., laser field) are marked υ₁ and υ₂, or ω₁ and ω₂ (angular frequency), respectively. The energy of the levels is indicated on FIG. 1 by the respective equivalent frequency Ω₁=E₁/h (with i=1 . . . 3). FIG. 1 with the arrow configuration depicted therein shows why this excitation scheme is referred to as the “Λ-system”. In these excitation schemes, and especially within the context of the dynamics of dark resonances, the following (known) variables are of importance (see FIG. 1), specifically:

Two-photon detuning δ_{L}:

δ_{L}=(Ω₃−Ω₂)−ω₂ (1)

and Raman detuning δ_{R}:

δ_{R}=Δ₂₁−(ω₁−ω₂) (2)

wherein Δ₂₁=Ω₂−Ω₁ is the splitting frequency of the levels |1> and |2>.

These variables can be used to discuss the behavior of dark resonances given at variable excitation frequencies (frequencies of the bichromatic electromagnetic field) in an especially clear manner.

Raman detuning δ_{R} can be regarded as the frequency difference between the ground state hyperfine structure splitting Δ₂₁=ν_{HFS} (the frequency measures approx. 6.8 GHz for the alkali metal isotope ⁸⁷Rb) and a microwave generator frequency ν_{RF}. As evident from FIGS. 2A and 2B (which depict the dispersion D, and absorption A, respectively, of CPT dark resonances (in any units desired)), the dark resonance only arises in a very small frequency interval about δ_{R}=0 Hz. The change in energy (or equivalently the change in frequencies ω₁ and ω₂ on FIG. 1) of the atomic/molecular level under the influence of external magnetic fields is reflected precisely in the change in δ_{R} (see equation 2). Accordingly, the achievable sensitivity when determining the magnetic field is directly correlated with the frequency interval (at δ_{R}=0) in which the dark resonance arises. This property of “sensitivity” on the part of dark resonances relative to Raman detuning δ_{R}≠0 is hence an essential point.

Raman detuning is frequently controlled by a radio frequency (RF) generator or microwave generator, which modulates a laser. The generator can be easily adjusted to within an accuracy of 0.1 . . . 0.001 Hz in this frequency range. Therefore, the CPT resonance line can also be “scanned” with this accuracy.

The frequency width (=line width) of the CPT resonance is substantially prescribed by the so-called decay rate of the ground state coherence, which is essentially a measure of the life of the dark resonance. This decay rate is basically composed of several factors, which in turn can be categorized as intrinsic decay rates (caused by quantum dynamics) (e.g., the spontaneous transition of the population from level |2> to level |1>) and external decay processes.

In order to achieve as small a line width of dark resonance (and hence a high sensitivity of the magnetometer) as possible, the decay rate of the ground state coherence must be minimized. This is achieved by selecting the level arrangement of the quantum system in such a way that the transition from level |2> to level |1> is a so-called dipole-forbidden transition. In this case, the decay rate of the ground state coherence is largely determined by external influences (e.g., by collisions between the atoms in a dark state with a vessel wall).

The use of a so-called buffer gas greatly reduces the collision rate with the wall. Hence, the average free path length of the quantum systems pumped in the dark state is reduced significantly given a suitably selected buffer gas pressure. This results in a diffusion motion of the quantum system. As a result, the effect of the time-of-flight broadening of the dark resonance diminishes greatly.

In the end, the measures described yield effective lifetimes for ground state coherence measuring 1 . . . 30 ms. As a consequence, this means that the frequency width of dark resonance is significantly reduced. The sensitivity of the magnetometer hence increases in the same manner.

However, the buffer gas must satisfy the requirement that the decay rate of ground state coherence is not significantly increased by this gas (and the resulting collisions). Possible (buffer) gases with the required properties include the noble gases or molecular gases such as nitrogen and methane, etc. The electronic structure of these gases is such that there is only a slight overlap of the wave functions for the buffer gas and the wave functions for the ground states |1> and |2> of the quantum system situated in the dark state. However, even the slight overlap of these wave functions is responsible for a systematic frequency shift of dark resonance during a collision, which depends on the buffer gas density and the temperature of the buffer gas. The origin of the influence exerted by the dark resonance frequency during such a collision process involves the interplay between Van der Walls forces and exchange interactions of the quantum system and buffer gas.

This (undesired) frequency shift has a significant influence on the accuracy and long-term stability of the magnetometer. The magnetic field can no longer be inferred from the dark resonance frequency (see ensuing equation 3) based on the physical constant and frequency value of ν_{HFS}. In the presence of a buffer gas, these pressure and temperature-dependent frequency shifts are superposed by the undisturbed frequency ν⁰_{HFS} based on ν_{HFS}=ν⁰_{HFS}+ν_{buffer}.

As opposed to the “sensitivity” of the dark resonances relative to Raman detuning, insensitivity is contrasted against two-photon detuning δ_{L} (see equation 1). A quantum mechanical analysis reveals that the line widths (=frequency widths) of the optical transitions between the levels |1>-|3> and |2>-|3> are here relevant (see FIG. 1). For this reason, two-photon detuning δ_{L} can indeed assume values of 10 . . . 20% of the line width of these optical transitions (e.g., 50-100 MHz when using atomic rubidium vapor as the quantum system) without the dark resonance losing significantly in terms of signal height.

Therefore, no major requirements are placed on the laser stability. A free-running, i.e., unstable, laser is often sufficient.

The behavior of the CPT resonances is discussed based on the ⁸⁷Rb-D₁ line as a specific quantum system (in addition to numerous other possibilities). In addition to the ability of realizing Λ-type excitation schemes, the desired dipole-forbidden transition between the ground states arises in the case of rubidium (as in all other alkali metals).

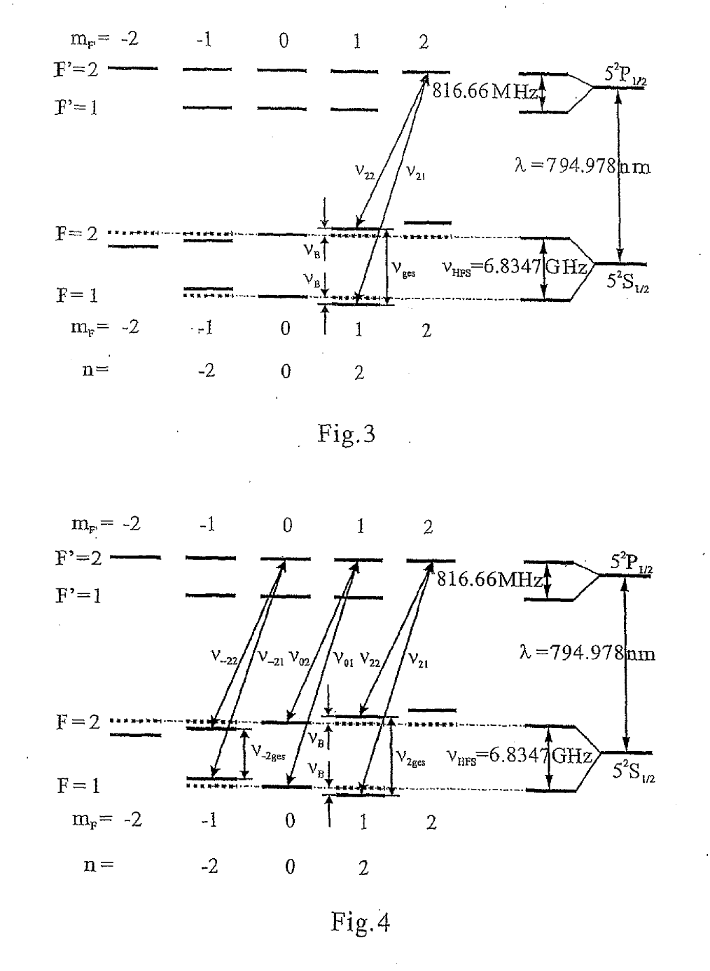

FIG. 3 shows the realization of an Λ-excitation scheme within the ⁸⁷Rb-hyperfine structure of the D₁ line. The special selection of ground states |1> and |2> in the form of the two magnetic sub-states |5² S_{1/2}F=1 m_{F}=1> and |5² S_{1/2}F=2 m_{F}=1> yields a magnetic field dependence of the ground state splitting frequency through the known Zeeman effect. Since this case involves ground states of the D-lines, the problem can be solved quantum mechanically without any disturbance equation. Therefore, the splitting can be indicated for “any” magnetic flux densities B.

FIG. 3 uses bold lines to schematically depict magnetic field-dependent CPT dark resonances in the ⁸⁷Rb-D₁ line: On FIG. 3, (F, m_{F}) and F′, m′_{F}) denote overall angular momentum quantum numbers of magnetic (sub) quantum numbers for the ground state and excited state, ν_{B} the frequency shifting owing to the Zeeman effect, ν_{ges} the total frequency splitting in the magnetic field, ν_{HFS} the frequency of the splitting of the ground state (without magnetic field), ν₂₁ and ν₂₂ the frequencies of the electromagnetic field that induce excitation in the Λ-system with the number N=+2, and the λ wavelength of the transition |5² S_{1/2}→|5² P_{1/2}. The dependence of ν_{ges}=ν_{HFS}+2ν_{B} is generally evident from FIG. 3. In the area of smaller fields (e.g., |B|<<1 Tesla), the known Breit-Rabi formula in its linearized form (linear Zeeman effect) can be used. Numbering the CPT dark resonances with n=m_{F1}+m_{F2} and selecting Δm=m_{F2}−m_{F1} yields the following for ν_{ges} (B—magnetic flux density [T]):

$${v}_{ges} = {v}_{HFS} + \frac{{μ}_{B}}{( 2 {I}_{k} + 1 ) h} [ n ( {g}_{J} - {g}_{I} ) + 8 m {g}_{I} ] B \qquad ( 3 )$$

The variables g_{J}, g_{I} and Iₖ in equation 3 stand for the fine structure Landé/factor (g_{J}) or the atomic nucleus Landé factor (g_{I}) and the nuclear spin (Iₖ), and μ_{B} denotes the Bohr magneton. These variables are known, and presented in tabular form.

The linearized form of the Breit-Rabi formula will only be specified in subsequent passages to more easily notate the equations. The described principles are also valid when using the exact form of the Breit-Rabi formula.

The frequency ν_{HFS} corresponds to the splitting frequency of the ground states at B=0 (see FIG. 3), and is very precisely known for the alkalies. This splitting frequency ν_{HFS} measures 6,834 682 610 904 29(9) GHz for ⁸⁷Rb, for example. The g_{J} factor depends on the respective electron configuration. A shifting coefficient C=n·7 kHz/μT can be calculated for the ⁸⁷Rb-D₁ line from equation 3. This yields a value of 2 ν_{B}/B=14 kHz/μT for the Λ-system depicted on FIG. 3.

Magnetic fields can in principle (e.g., see WO 2004/051299; or Peter D. D. Schwindt et al., “Chip-scale atomic magnetometer”, Applied Physics Letters, Vol. 85, No. 26, Dec. 27, 2004, p. 6409-6411) be measured using the single Λ-system depicted on FIG. 3. The dark resonance would here have to be generated with a circular polarized, bichromatic radiation field with frequency components ν₁ and ν₂. The two frequency components of the laser field can be realized in the form of sidebands that arise by modulating the laser.

If, subsequently, the frequency of the modulation generator is continuously kept at (ν₂₁−ν₂₂)−ν_{ges}=0 by a control loop, the frequency of the modulation generator ν_{mod}=½(ν₂₁−ν₂₂) can be used according to equation 3 to infer the magnetic field B. The accuracy of the magnetometer is limited by systematic (error) influences, which affect the frequency position of the CPT resonance in an undesired manner. As already described, these systematic frequency shifts result from the interaction between the quantum systems in a dark state (e.g., atoms or molecules) and a buffer gas (see further above) on the one hand, and the intrinsic accuracy of the frequency measurement with which the CPT resonance frequency can be determined on the other.

However, this means that the frequency ν_{HFS} depends significantly on the used buffer gas, the buffer gas pressure and the ambient temperature. For example, the frequency of the dark resonance can already shift by 5 Hz/K given a variable temperature. Given a change in the buffer gas temperature of 1 K, this drift could not be differentiated from a change in the B field measuring 360 pT. In view of the otherwise achievable accuracy of ΔB≈1 . . . 10 pT, this represents a considerable limitation. Avoiding temperature drift would necessitate a complicated temperature stabilization of a measuring cell, which incorporates the quantum systems (e.g., rubidium, cesium).

The required accuracy of temperature stabilization would have to measure ΔT≈0.01 K in the cited example to achieve the otherwise conceivable accuracies. A thermalized cell notwithstanding, the ability to measure magnetic fields with the highest accuracy and repeatability using a system according to FIG. 3 is lost, since a hysteresis-free repeatability of the cell temperature is technically impossible, despite the temperature stabilization.

Another source of errors in the known magnetic field measurement with dark resonance lies in the fact that the stability of, the RF generator used to determine ν_{ges} also limits the accuracy of the B-field measurement. Conventional and still financially affordable generators exhibit a long-term stability of Δν/ν≈10⁻⁹ per month. Therefore, a drift of approx. 7 Hz per month results at a ν_{ges}≈ν_{HFS}=6.8 GHz. This corresponds to a systematic drift of the magnetometer of 500 pT per month.

A modified measurement principle is described in the article by R. Lammegger et al., “A Magnetometer Based on Quantum Interference Effects”, 13^{th} International School on Quantum Electronics: Laser Physics and Applications, Proceedings of SPIE Vol 5830, Bellingham, Wash., 2005, pages 176-180 (similarly, see: A. Huss et al., “Polarization-dependent sensitivity of level-crossing, coherent-population-trapping resonances to stray magnetic fields”, September 2006, Journal of the Optical Society of America B (Optical Physics), Opt. Soc. America, USA; AN 9057678; INSPEC/IEE database or Vol. 23, pp. 1729-1736), wherein the suitability of CPT resonances in a “Hanle” configuration is described relative to an application in a magnetometer, and wherein the measurement principle hinges on a level crossing, i.e., the CPT resonances only arise if and when the entire magnetic field to which the atoms (specifically rubidium atoms) are exposed has the value B=0. Therefore, the CPT resonance serves as the “0-field marker” in this magnetometer. The applied magnetic field is consequently determined in such a way that a compensation magnetic field is applied to the magnetic field to be measured; this compensation magnetic field is determined in terms of control technique in such a way that the CPT resonance arises. Since the latter only arises given a magnetic field B=0, the magnetic field to be measured and the compensation magnetic field must be identical in size, but oppositely aligned. The compensation magnetic field is generated by a solenoid, a long cylindrical coil, wherein the magnetic field to be measured is in the end elicited via the coil current of this solenoid. As a result, the measurement principle is based on a current measurement.

Disclosed in the article by E. B. Aleksandrov, “A new model of quantum magnetometer: a single-cell Cs-K tandem based on four-quantum resonance in <39>K atoms” July 2000; Technical Physics; Vol. 45, No. 7; MAIK Nauka; Russia; AN 6716360; IN-SPEC/IEE database, pp. 931-936, is an optically pumped cesium-potassium (tandem) magnetometer, such an optically pumped magnetometer being fundamentally different from a CPT magnetometer, however. In optically pumped magnetometers, the depolarization of the alkali vapor is achieved with the help of a modulated AC magnetic field; the optical excitation takes place with an unmodulated laser or with a spectral lamp; such an excitation source would be insufficient for exciting CPT dark resonances.

The article by Hwang et al., “Quantum limit sensitive of coherent dark-state magnetometers”, May 19, 2002; Conference on lasers and electro-optics (CLEO 2002). Technical Digest. Post-conference edition. Long Beach, Calif., Trends in optics and photonics (TOPS); Washington, Wash.: OSA, US; AN XP010606401; NPL/EPO database, pp. 36-37 (similarly see also Brandt S. et al., “Magnetometry and frequency references with coherent dark states”, Jun. 17-21, 1996; Proceedings of 20^{th} Biennial Conference on Precision Electromagnetic Measurements; Braunschweig, Germany; AN 5483666; INSPEC/IEE database, p. 190), discusses the theoretically achievable sensitivity limit of a conventional dark state magnetometer based on the excitation of a single dark resonance, wherein in particular a “dark-state” magnetometer with interferometric structural design is described.

The article by Shirley J. H. et al., “Zeeman coherences and dark states in optically pumped cesium frequency standards”, Jun. 27, 1994, Precision Electromagnetic Measurements, 1994 Conference on Boulder, New York, N.Y. USA, IEEE; AN XP010123851; NPL/EPO database pp. 150-151, focuses on the avoidance of “trapped states” in the preparation region of cesium atomic beam atomic clocks, wherein special attention is paid to the problem of atomic clocks as opposed to magnetometers.

Similarly, US 2004/0202050 A1 also involves the operation of an atomic clock, wherein use is made among other things of the Zeeman effect to lock both the atomic clock frequency and the magnetic field to defined values.

It is now an object of the invention to provide a method and a device, respectively, for measuring magnetic fields, which enables a precise measurement even given extremely small magnetic fields, for example ranging from μG to a few G, over long periods of time. The goal here in particular is to be able to perform the measurement in such a way as to eliminate the systematic error influences discussed above, as manifested in the frequency of the ground state, meaning the frequency ν_{HFS} (p, T), and solely the magnetic field-dependent variable is to be measured (see second term in the above equation 3). The magnetic field B could then be measured free of the cited error influences, such as buffer gas, buffer gas temperature and pressure.

In order to achieve this object, the invention provides a method and a device for measuring magnetic fields as defined in the independent claims. Especially advantageous embodiments and further developments are indicated in the dependent claims.

In the measurement technique according to the invention, several dark resonances are coupled with each other, as will be explained in even greater detail below, wherein a polychromatic radiation is used as an electromagnetic field, in particular a light field or laser radiation with various frequency components. This polychromatic electromagnetic field can preferably be achieved in a multistage modulation process involving a laser as the radiation source. As opposed to prior art, a second modulation or mixing process is hence used, wherein a ring modulator or ring mixer is preferably employed to mix a low-frequency modulation signal with a first, high-frequency signal of a microwave generator. In this way, the mixing process yields the desired frequency components, in particular in the form of a double sideband structure, as will be explained in even greater detail below. In order to be able to acquire only the magnetic field-dependent frequency components or to achieve a simultaneous formation of all dark resonances of the system, it is best to select the first modulation frequency, the high-frequency modulation frequency, as equal to the splitting frequency ν_{HFS}, so that a value ν_{B} then results for the second, low-frequency modulation frequency, after tuning to the resonance, wherein this second modulation frequency can be dealt with completely separate from the first modulation frequency. The second modulation frequency is generated by a low-frequency generator, in particular a voltage/frequency converter or a digital-data-synthesis (DDS) frequency generator, which is permanently adjusted by means of a control loop in such a way that the Raman detuning is equal to 0 for all Λ-systems (CPT condition). The use of a ring modulator eliminates practically all limitations for the magnetic field to be measured (corresponding to the second modulation frequency). This advantage stems from the generally very high bandwidths (GHz range) of such mixers. By contrast, in case of a direct actuation of the HF generator, the bandwidths of the generator-internal (PLL) phase control loops would limit the maximum possible NF modulation frequency to approx. 100 kHz. In this way, magnetic fields of only up to a maximum of 0.1 G could be measured. By contrast, the use of a ring mixer makes it possible to utilize the entire measurement range (several Gauss) of the CPT magnetometer.

Another advantage from this type of modulation with a ring mixer is that an amplitude modulation is involved. In this type of modulation, only the sidebands of the first order arise (regardless of the modulation index). This helps bring about a situation where the multichromatic radiation contains only the desired frequency components. By contrast, the direct actuation of the HF generator with the second modulation frequency would imply a frequency modulation, wherein sidebands of a higher order of magnitude arise as a function of the modulation index, which can make the spectrum of dark resonances even more complicated.

In the described amplitude modulation of the ring mixer, carrier-less operation in which the HF modulation frequency is missing in the spectrum can also be easily achieved. This is advantageous for the measurement, since the accompanying dark resonance (with number n≈0) is not necessary anyway. This dark resonance only generates a disturbing signal background, which would have to be removed with a phase-sensitive detection.

In order to also enable a scan mode during measurement, it is favorable that the input of the voltage/frequency converter to be selectively activatable at the output of a ramp generator. This mode of operation makes it possible to scan the low-frequency sidebands and record the dark resonances. In the locked mode of operation, with an active servo loop, the low-frequency sidebands are coupled with the dark states split open according to the Zeeman effect.

As already mentioned repeatedly, a laser is preferably used as the source for the electromagnetic radiation, and the radiation source in particular is constituted by a VCSEL laser. A temperature control loop can be allocated to this VCSEL laser for purposes of temperature stabilization.

The multiple modulation signal is best routed to the radiation source via an attenuator, so that the modulation signal can be applied to the latter with the optimum energy.

In the case of using alkali metal atoms in the measurement cell, it has proven especially advantageous for the modulation frequency generator to generate a first modulation frequency in a range of several GHz, in particular 3.4 GHz or 6.8 GHz in the case of ⁸⁷Rb, and for the second modulation frequency to measure up to several MHz, thereby achieving a measurement range of several Gauss (G).

The invention will be described in even greater detail below based on preferred exemplary embodiments, without being limited thereto, however, and with reference to the drawing. The drawing specifically shows:

FIG. 1 a basic scheme already explained above to illustrate the known three-level system in which CPT dark resonances can be observed;

FIGS. 2A and 2B diagrams depicting the dispersion D and absorption A, respectively, of CPT dark resonances (in arbitrary units) over Raman detuning δ_{R} (kHz), specifically for the parameters 2-photon detuning δ_{L}=0 Hz, Rabi frequencies g₁=g₂=20 kHz, and decay rate of ground state=100 Hz;

FIG. 3 the also already explained known scheme for the magnetic field-dependent CPT dark resonances in the ⁸⁷Rb-D₁ line to illustrate the frequency shifts ν_{B} owing to the Zeeman effect during the various excitations in the Λ-system;

FIG. 4 a scheme comparable to the one on FIG. 3, except that the simultaneous coupling of several dark resonances according to the invention is illustrated based on the example of the ⁸⁷Rb-D₁ line, wherein the formed Λ-systems are numbered with the indices n=−2, 0, 2;

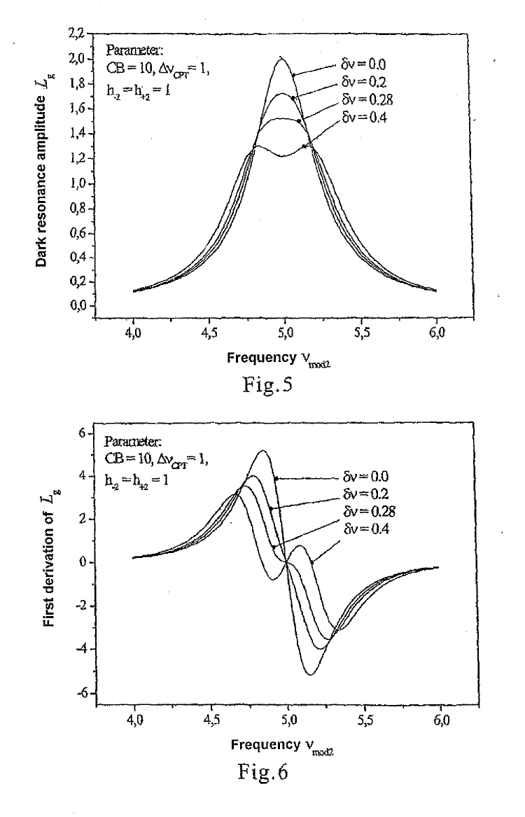

FIG. 5 a diagram depicting the entire dark resonance amplitude given at such a system with coupled dark resonances, specifically with various HF oscillator detunings δ_{ν} in units of the CPT line width Δν_{CPT}, wherein the entire dark resonance amplitude L_{g}=Lₐ₋₂+Lₐ₊₂ is shown for four different frequency detunings δ_{ν};

FIG. 6 in a diagram for the same HF oscillator detunings as on FIG. 5, the respective curves, corresponding to the 1^{st} derivation of the entire dark resonance amplitude;

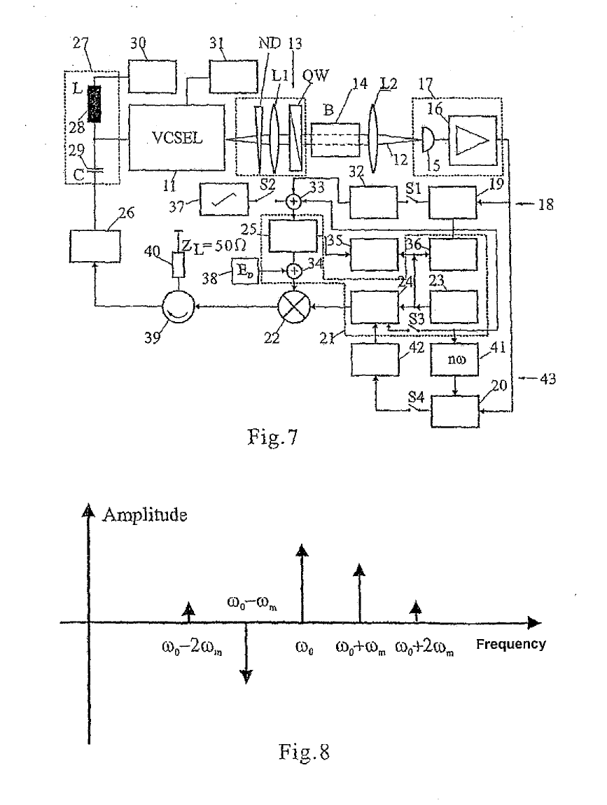

FIG. 7 a scheme resembling a block diagram to illustrate a preferred exemplary embodiment for the measurement device according to the invention;

FIG. 8 a spectral composition of the signal required for the coupling of dark resonances, at the output of the tunable frequency generator according to FIG. 7, consisting of carrier frequency and sidebands of the first and second order of magnitude;

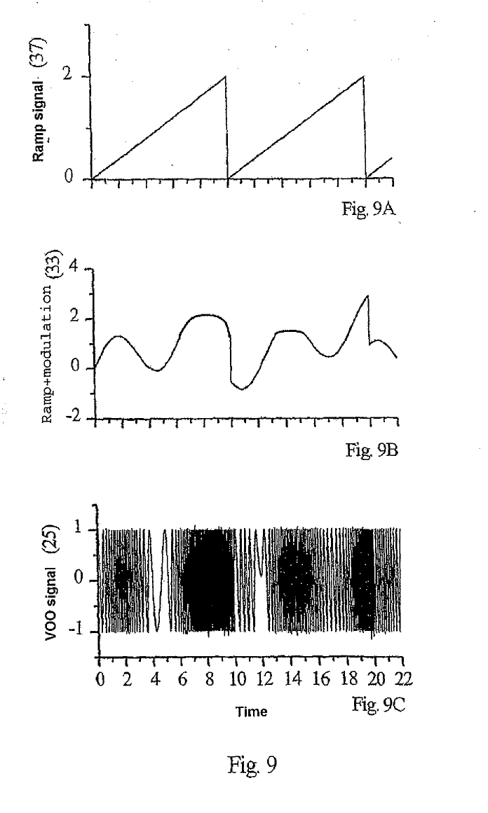

FIG. 9, on partial FIGS. 9A, 9B and 9C, a ramp signal (FIG. 9A) arising at the output of the frequency generator on FIG. 7, a superposed ramp and modulation signal (FIG. 9B) at the output of the adding unit on FIG. 7, and a correspondingly modulated output signal of the frequency generator (FIG. 9C);

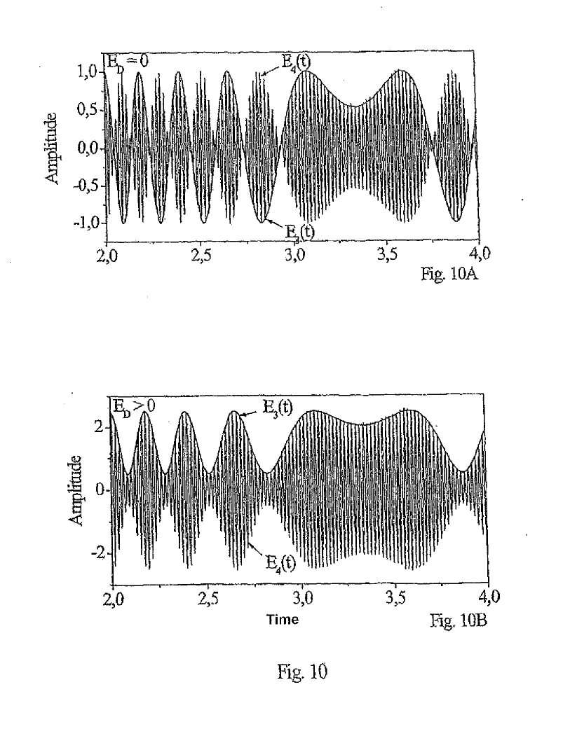

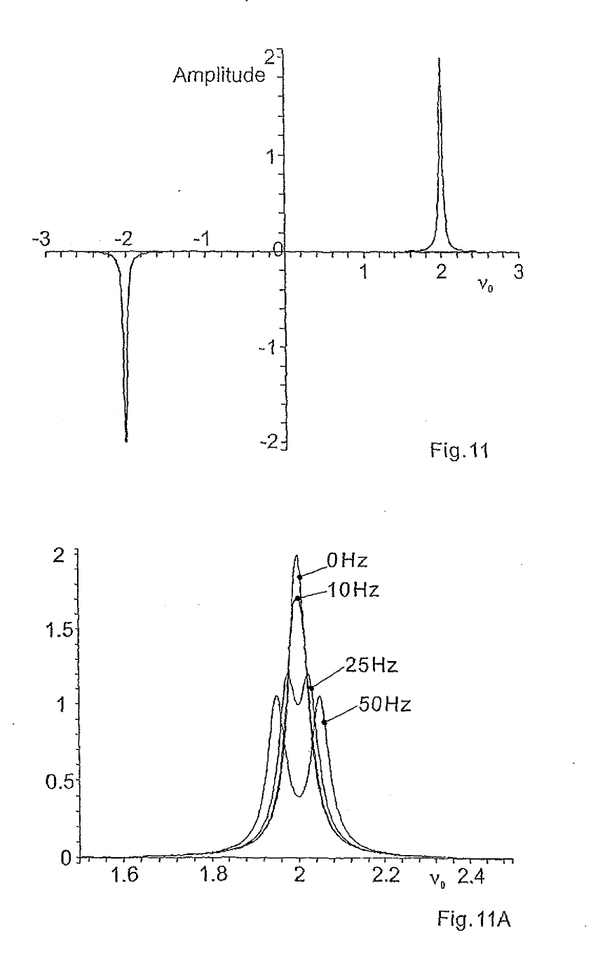

FIG. 10, on partial FIGS. 10A and 10B, the input signal coming from the adding unit according to FIG. 7, and the high-frequency output signal (GHz range) of the mixer depicted on FIG. 7, specifically once without (FIG. 10A) and once with direct voltage share E_{D} (FIG. 10B);

FIGS. 11 to 14 frequency modulation spectra (FM spectra) given at a varying selection of modulation and resonance parameters for the coupled dark resonances (as to be explained in greater detail below), wherein detailed representations with the corresponding parameter studies are indicated in the respective partial FIGS. 11A to 13A; and

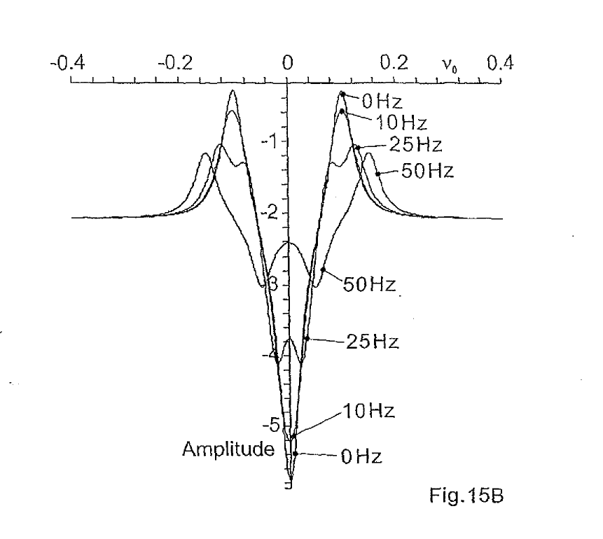

FIGS. 15A and 15B FM spectra of the coupled dark resonances for a general set of modulation and resonance parameters.

As already mentioned above, the systematic error influences given in prior art and specified at the outset based on FIGS. 1 to 3 are eliminated in the measurement technique according to the invention by virtue of the fact that the frequency of the ground state ν_{HFS}, which depends on external influences (such as pressure, temperature and type of buffer gas) on the quantum system that is in the dark state, is formally split from that term in equation 3 that depends on magnetic field B. As a consequence, the frequencies ν_{HFS} and ν_{B} are generated separately, wherein the sole measurement of the variable proportional to the frequency ν_{B} (see second part of the above equation 3) enables a determination of magnetic field B, in which the mentioned error influences are avoided.

This becomes evident based on the scheme on FIG. 4, which depicts three Λ-systems with a polychromatic electromagnetic field (light wave field) with frequency components ν₋₂₁ . . . ν₂₂. The formed Λ-systems are numbered on FIG. 4 with the indices n=−2, 0, 2; the frequency components j of the electromagnetic field that induce excitation in the Λ-system with the number n=i are indicated with νᵢⱼ (j=1, 2 and i=−2, 0, +2); ν_{iges} denotes the entire frequency splitting in the magnetic field of the ground states of the Λ-system with the number n=i. The remaining symbols are identical in meaning with those on FIG. 3. The polychromatic field according to FIG. 4 can technically be achieved in a multistage modulation process.

In a first modulation stage, the laser (laser frequency ν_{L}) is modulated by an RF-(HF-) signal with the frequency ν_{mod1}≅½ ν_{HFS}. This yields a sideband structure for the laser radiation in the form of ν₀₁=ν_{L}+ν_{mod1}; ν_{L}; and ν₀₂=ν_{L}−ν_{mod1}; a total of three frequency components are here obtained (the laser frequency measures roughly 377 THz in the case of ⁸⁷Rb as the quantum system).

If the RF generator frequency is assumed to be variable, detuning the frequency ν_{mod1} produces only the dark resonance with the number n=0 at the location ν_{mod1}=½ν_{HFS} (δ_{R}=0; see above equation 2). The Λ-system n=0 is hence formed by the sidebands ν₀₁=ν_{L}+½ν_{HFS} and =ν₀₂=ν_{L}−½ ν_{HFS}. Due to known circumstances in nuclear physics, this dark resonance (n=0) “only” depends on the magnetic field in the second order of magnitude. The position of this dark resonance can hence (initially) be assumed to be independent of the magnetic field for the observations pursued here. However, ν_{HFS}=ν_{HFS} (p, T) continues to apply, i.e., the dependence of pressure p and temperature T of the buffer gas is a given. In order to now, in addition to the Λ-system n=0, form the two Λ-systems that depend on the magnetic field B with the numbers n=−2 and n=2, FIG. 4 states that the additional frequency components ν₋₂₁, ν₋₂₂ and ν₊₂₁, ν₊₂₂ must be generated. This is accomplished by means of a second mixing process to be explained in more detail below based on FIG. 7. In this mixing process, the RF signal, meaning the first modulation frequency ν_{mod1}, is again mixed with a second, lower-frequency modulation signal ν_{mod2}, preferably by means of a ring modulator (ring mixer), see FIG. 7. In this way, the mixing process yields the frequency components ν_{-2RF}+ν_{mod1}−ν_{mod2}, ν_{ORF}=ν_{mod1} and ν_{+2RF}=ν_{mod1}+ν_{mod2} in the microwave range. While the way in which this modulation is achieved is in itself not critical with respect to the principle of action, the use of a ring modulator does offer essential technological advantages, as will be explained in greater detail below.

If the two mixing processes are now taken together in terms of their effect (as already stated, the first modulation process only involves the modulation of the laser, e.g., current modulation for semiconductor laser diodes), the result is a multichromatic electromagnetic field (laser field) with the following frequency components:

ν₂₂=ν_{L}−(ν_{mod1}+ν_{mod2})

ν₀₂=ν_{L}−ν_{mod1}

ν₋₂₂=ν_{L}−(ν_{mod1}−ν_{mod2})

ν_{L}=ν_{L}

ν₋₂₁=ν_{L}+(ν_{mod1}−ν_{mod2})

ν₀₁=ν_{L}+ν_{mod1}

ν₂₁=ν_{L}+(ν_{mod1}+ν_{mod2}) (4)

A comparison of these correlations with the excitation scheme on FIG. 4 demonstrates that all necessary frequency components are present for exciting all Λ-systems. A dark resonance, i.e., a change in the absorption of the alkali vapor here regarded as an example of a quantum system; see also FIG. 2, arises precisely when the condition δ_{R}=0 is satisfied for one of the Λ-systems presented on FIG. 4. A simultaneous formation of all three dark resonances is hence given under the condition δ_{R-2}=δ_{R0}=δ_{R+2}=0 (see equation 2). In a multichromatic radiation field of the kind described by equation 4, this condition is directly achieved when the following applies:

$${v}_{mod 1} = 1 / 2 {v}_{HFS} \\ {v}_{mod 2} = {v}_{B} = \frac{{μ}_{B}}{2 \cdot ( 2 {I}_{l} + 1 )} [ \vert n \vert ( {g}_{J} - {g}_{I} ) + 8 Δ m {g}_{I} ] B \qquad ( 5 )$$

As evident from these equations (5), the modulation frequencies ν_{mod1} and ν_{mod2} can be treated separately. ν_{mod1}=½ν_{HFS} is usually inserted and left as is. The second modulation frequency ν_{mod2} is generated by a low-frequency generator, which is permanently adjusted via a control loop in such a way that δ_{R-2}=δ_{R+2}=0 remains satisfied, meaning that the CPT condition is given. As already mentioned, the linearized Breit-Rabi formula is only indicated to more easily notate the equations. The measurement principle also retains its validity when using the exact form of the Breit-Rabi formula.

In a technical realization, the magnetic field measurement according to equations 5 can be performed via the much easier determination of ν_{mod2} (ν_{mod2}≦MHz range). The key advantage that results from this splitting in terms of the accuracy and stability of the magnetic field is that it makes this measurement principle extremely precise and stable over a long term.

A commercially available, highly stable time base in the form of a temperature-stabilized quartz oscillator (OCXO—oven-controlled crystal oscillator) with a stability of approx. Δν/ν≈10⁻⁹ per month can be used for generating the RF signals ν_{mod1} (in the GHz range). If the magnetic field were to take place while measuring the frequency of only one dark resonance using the RF signal, as is the case in prior art, a systematic drift (=fictive magnetic field) of approx. 500 pT per month (numerical values for ⁸⁷Rb) would result despite the high stability.

The ability described above of separately determining ν_{mod2} reduces the systematic errors attributable to the oscillator drift during a magnetic field determination over ν_{mod2} to ΔB_{syst}=ν_{mod2}/ν_{HFS}·ΔB≦0.5/7000·500 pT=0.035 pT. (These numbers are assumed for the case of a ⁸⁷Rb magnetometer during magnetic field measurements in the order of magnitude of 0.7 G [symbol] ν_{mod2}≈0.5 MHz (terrestrial magnetic field≈0.5 G).) The multistage modulation process hence enables a very significant reduction (e.g., by a factor of 7000) of the systematic error influences caused by the oscillator drift.

Splitting modulation into two stages enables the separate evaluation of the frequency ν_{mod2} that depends on the magnetic field B. This measure makes it possible to eliminate the systematic (external) influences (e.g., by the buffer gas) on the frequency Δ₁₂ (or ν_{HFS}) of the quantum system, since only the component ν_{B}=ν_{mod2} is used for magnetic field determination. As shown by a comparison of equation (3) and equation (5), the frequency ν_{B}=ν_{mod2} does not depend on the potentially influenced (disturbed) frequency ν_{HFS}. It is important that ν_{mod1} exerts no influence on the position of the dark resonances (and hence also on ν_{mod2}). This decoupling additionally ensures that the systematic influences (e.g., owing to the pressure and temperature of a buffer gas) on the position of the signal of the coupled dark resonances can be eliminated in a certain area (depending on the width of the dark resonance (see next equation 9)), even without any active correction by means of an additional control loop. The systematic error of the B-field measurement owing to temperature influences trends toward zero.

As will be explained further below, a signal can be derived from equation (39) that enables an active correction (using a control loop 43 from FIG. 7) of the frequency ν_{mod1}. In this way, maintaining the decoupling described above no longer depends on the line width of the dark resonance. As a result, the magnetometer can be operated at peak resolution (i.e., at the lowest line widths for the dark resonances). Even systematic error influences of the variable ν_{HFS}−2ν_{mod1}>Δν_{CPT} no longer come into play.

At small values for Raman detuning δ_{R-2}, δ_{R+2}≈200 Hz <<Δνₙₒₘ ≈6 MHz and two-photon detuning δ_{L}<<Δ_{doppler}≈500 MHz, the frequency dependence of the absorption and frequency dependence of the dispersion of the medium (see also FIG. 2) can be described with simple Lorentz functions:

$${L}_{a - 2} = \frac{{h}_{- 2}}{4} \cdot \frac{Δ {v}_{CPT}^{2}}{{( δ v - CB + 2 {v}_{mod 2} )}^{2} + \frac{1}{4} Δ {v}_{CPT}^{2}} \\ {L}_{a + 2} = \frac{{h}_{+ 2}}{4} \cdot \frac{Δ {v}_{CPT}^{2}}{{( δ v + CB - 2 {v}_{mod 2} )}^{2} + \frac{1}{4} Δ {v}_{CPT}^{2}} \qquad ( 6 )$$

Index a means that a Lorentz function with absorptive nature is involved. Index −2 or +2 denotes the number n of the dark resonance. Variable hₙ, with n=−2 or +2, sets the height (signal strength) of the dark resonance with the number n. A good approximation of h₋₂=h₊₂ is assumed in the following observations. This approximation is justified for dark resonances in buffer gas cells, since the lifetimes of the excited states are greatly reduced by the buffer gas. Despite the optical pumping through the σ-polarized electromagnetic field (laser light), increased numbers of spontaneous decays in all m_{F} states bring about an equal distribution of population (occupation) over all m_{F} states.

The additional expressions in the denominator of equation 6 mean as follows: The variable Δν_{CPT} is defined as the full width of the dark resonance at half the signal height (FWHM—full width at half maximum). Also applicable: δ_{R-2}=δν−CB+2ν_{mod2} or δ_{R+2}=δν+CB−2ν_{mod2} are the corresponding Raman detunings of the dark resonances with the number n. The variable δν=ν_{HFS}−2ν_{mod1} is the frequency difference between the dark resonance n=0 (0-0 transition) and the RF oscillator frequency ν_{mod1}. As a consequence, the value δν=0 is obtained for a perfectly tuned RF oscillator.

Since both dark resonances are coupled via the multichromatic laser field, only the variable L_{g}=Lₐ₋₂+Lₐ₊₂ can be detected. During a magnetic field measurement, the LF generator frequency ν_{mod2} is the variable number according to equation 6. The NF generator is tuned via a control loop in such a way that ν_{mod2} corresponds precisely with the frequency at which the overall absorption reaches its maximum (L_{g}(ν_{mod2})=max.). This is also depicted on FIG. 5, which illustrates the overall dark resonance amplitude L_{g}=Lₐ₋₂+Lₐ₊₂ at different RF oscillator detunings δν (in units for the CPT line width Δν_{CPT}). At ≦ 3/6 Δν_{CPT}, only a single global maximum is given when ν_{mod2}=½CB, which serves as the lock point for the LF oscillator (which generates ν_{mod2}). Other parameters on FIG. 5 include: magnetic field (in frequency units) CB=10, individual dark resonance amplitude h₋₂=h₊₂=1. (The numerical values of the parameters are freely selected, so that the basic principle can be graphically illustrated.)

The variable CB (a frequency unit) is functionally correlated with the external magnetic field B due to the Zeeman effect (see equation 3); just as δν, it is a parameter in the equation of L_{g}=Lₐ₋₂+Lₐ₊₂.

It is guaranteed that accuracy will be maintained if the following applies with respect to the overall dark resonance amplitude:

$$Lg ( {v}_{mod 2} ) = \frac{1}{2} CB ,$$

and this also applies when the detuning of the RF oscillator δν≠0.

This can be checked by forming the 1^{st} derivation of equation 6, see also FIG. 6.

As evident from FIGS. 5 and 6, three real zeros are obtained in a general case. The position of these zeros can be analytically reached by solving the following equation:

$$\frac{d {L}_{g}}{d {v}_{mod 2}} = {h}_{+ 2} \frac{Δ {v}_{CPT}^{2} ( δ v + CB - 2 {v}_{mod 2} )}{{[ {( δ v + CB - 2 {v}_{mod 2} )}^{2} + \frac{1}{4} {Δv}_{cpt}^{2} ]}^{2}} - {h}_{- 2} \frac{Δ {v}_{CPT}^{2} ( δ v - CB + 2 {v}_{mod 2} )}{{[ {( δ v - CB + 2 {v}_{mod 2} )}^{2} + \frac{1}{4} Δ {v}_{CPT}^{2} ]}^{2}} = 0 \qquad ( 7 )$$

With the condition h₊₂=h₋₂ (which is very well satisfied, as shown), this yields the following zero positions:

$${v}_{N 1 , 3} = \frac{1}{2} CB \pm \frac{1}{4} \sqrt{- 4 δ {v}^{2} + 4 \sqrt{δ {v}^{2} Δ {v}_{CPT}^{2} + 4 δ {v}^{4}} - Δ {v}_{CPT}^{2}} \\ {v}_{N 2} = \frac{1}{2} • CB \qquad ( 8 )$$

Zero ν_{N2} here corresponds to a fixed point (see FIG. 6), which lies strictly at

$${v}_{mod 2} = \frac{1}{2} CB .$$

These zeros correspond to a maximum of Lg at point

$${v}_{mod 2} = \frac{1}{2} CB ,$$

and are independent of the RF generator detuning ν_{mod1}, independent of ν_{HFS}=ν_{HFS}(p, T) and independent of the CPT line width Δν_{CPT}.

A suitable control flank is achieved during technical realization via a phase-sensitive detection of L_{g}, wherein this case involves a conventional lock-in technique. In such a detection method, the 1^{st} derivation of L_{g} (as depicted on FIG. 6) is generated given the suitable selection of the modulation parameters—the LF generator is modulated again accordingly. As a result, only the point

$${v}_{mod 2} = {v}_{N 2} = \frac{1}{2} CB$$

is possible as the clear lock point for the LF generator. However, a specific limit for δν cannot be exceeded. This limit is characterized by the disappearance of the 2^{nd} derivation of L_{g} at point

$${v}_{mod 2} = {v}_{N 2} = \frac{1}{2} CB .$$

The above yields the following condition for the RF generator detuning δν:

$$δ v = ( {v}_{HFS} - 2 {v}_{mod 1} ) \leq \frac{\sqrt{3}}{6} Δ {v}_{CPT} \approx 0 , 289 Δ {v}_{CPT} \qquad ( 9 )$$

At line widths of Δν_{CPT}≈100 . . . 200 Hz, a still tolerable drift of the RF oscillator of approx. δν≈30 . . . 60 Hz comes about. However, this limit is not exceeded at an oscillator stability of Δν/ν=10⁻⁹ given ν_{mod}=ν_{HFS}≅3.4 GHz.

A control loop (see control loop 43 on FIG. 7) actively corrects frequency deviations of the oscillator (23 on FIG. 7) from the nominal frequency. This control loop can be operated with a large time constant, since the accuracy of the magnetometer is not influenced by a frequency drift δν≠0.

The description of the measurement principle did not take into account the CPT resonance with the number n=0. During the phase-sensitive detection of dark resonances with the numbers n=±2, only the LF generator is modulated with the frequency used as the beat frequency while demodulating the photodiode signal. As a consequence, only the signal for dark resonance with the number n=±2 visibly arises at the output of a lock-in amplifier placed downstream from the photodiode (see FIG. 7). The signal background generated by the dark resonance n=0 can hence be disregarded.

In addition, a carrier-less operation of the ring mixer makes it possible to avoid the generation of dark resonance n=0 entirely, as mentioned.

The dark resonances are detected with a phase-sensitive test (lock-in techniques), so as to obtain a suitable control flank with a zero crossing for stabilizing the LF oscillator. Analysis shows that the stabilization point coincides with the line centroid, as long as the frequency drift of the RF oscillator (and/or the drift of ν_{HFS}) does not exceed approx. 30% of the achieved CPT resonance width. Given the typical CPT line widths Δν_{CPT}≈100 . . . 200 Hz and the typical drift of conventionally obtainable quartz oscillators of approx. 10⁻⁹ per month, it can be expected that the deviation of the RF oscillator frequency will virtually never exit the permissible range. Since the frequency of the line centroid (=lock point) is linked with the external magnetic field by very precisely known correlations, the present technique for coupling of several dark resonances can be used to realize a magnetometer that operates practically drift-free. The expanded analysis (presented further below) will describe a method in which an additional control loop 43 (see FIG. 7) can be used to offset even the largest deviations in oscillator frequency.

In physics and technology alike, frequency measurements rank among the most precise and best researched measurement methods. In the final analysis, the measurement principle of the magnetometer is based on the determination of a differential frequency for two atomic (molecular) transition frequencies. The measured frequency can hence be linked with the outside magnetic field acting on the quantum systems using precisely known quantum mechanical correlations.

The block diagram on FIG. 7 shows a diagrammatic view of an embodiment of such a CPT magnetometer, the principle of which was described above. The depicted device 10 for magnetic field measurement contains a laser device as the radiation source 11 for emitting electromagnetic radiation, in particular a VCSEL laser, the laser beam 12 from which is directed via optical elements 13 (including gray Filters ND, lens L1 and λ/4 plates (QW) through a measurement cell 14 and behind that via a lens L2 onto a photodiode 15. The VCSEL laser 11 has a frequency of approx. 377 THz (in the case of ⁸⁷RB), for example. The measurement cell 14 is preferably filled with a buffer gas, and contains the quantum systems to be excited, for example Rb or Cs atoms. The diameter of the laser beam 12 in the area of the measurement cell 14 measures approx. 2-8 mm, for example, wherein sufficiently narrow dark resonances can be achieved with a sufficient magnetometer resolution, as experiments have demonstrated. The quarter-wavelength delay plates (λ/4 plates) QW provided under the optical elements triggers a circular polarization. In this way, several dark resonances of varying frequency (Zeeman effect) are created via paired σ-transitions. The photodiode 15 is a low-noise photodiode; the signal-to-noise (S/N) ratio is also influenced by the temperature, length, pressure, etc., of the measurement cell 14, wherein a high S/N ratio can be achieved given a correct tuning of these parameters, and in particular given the use of Rb or Cs in the measurement cell 14. It has been shown that the S/N ratio can be additionally increased by heating the measurement cell 14 to approx. 30°-60° C. Further, even if not shown on FIG. 7, a temperature stabilization for the measurement cell 14 is advantageous for this purpose.

Placed downstream from the low-noise photodiode 15 is an especially low-noise amplifier 16, wherein the photodiode 15 and the amplifier 16 together belong to a detector unit 17 for the magnetic field B to be measured, and to which the measurement cell 14 is exposed.

The optical part of the device 10 mentioned above can largely be free of metal, so that this part does not itself cause any magnetic fields; in particular, the measurement cell 14 can be easily connected with multimode fiber optics.

The detector 17 has allocated to it a control loop 18 with two lock-in amplifiers 19, 20, which serve to lock (“lock in”) onto the detected dark resonance frequency, as will be explained in greater detail below, and since they are of conventional design, will not be described in any more detail.

For purposes of the measurement to be performed, the laser radiation 12 (or the accompanying electrical signal) is subjected to multistage modulation by means of a modulation unit 21 and a mixer 22. The modulation unit 21 contains a temperature stabilized quartz oscillator 23 (OCXO—oven controlled crystal oscillator), downstream from which is an RF synthesizer (RF generator) 24, in order to firmly tune the first modulation frequency, for example to a value of 6.8 GHz in the case of ⁸⁷Rb, at a frequency of the RF generator 24 of 3.4 GHz. The oscillator reference unit 23 is preferably a known, highly stable precision oscillator with low phase noise and a short-term stability of ≦4·10⁻¹³, as well as a drift of ≦10⁻⁹ per month. The high-frequency first modulation signal obtained in this way is routed to the mixer 22, which is designed as a ring mixer, where the HF modulation signal is modulated with a second, low-frequency modulation signal generated by a tunable (low) frequency generator 25 in the form of a voltage/frequency converter or a digital-data-synthesis (DDS) generator. As mentioned, the first, high-frequency modulation frequency of the oscillator 24 is set by the control loop 43 to the frequency

$${v}_{mod 1} = \frac{1}{4} ( {v}_{+ 2 ges} + {v}_{- 2 ges} ) \approx \frac{1}{2} {v}_{HFS} \approx 3.4 GHz ( {}^{Rb} 87 ) ,$$

while the low-frequency second modulation frequency constitutes the measure for the frequency ν_{B}, and consequently is adjusted with the help of an electronic servo or control loop yet to be explained in greater detail.

The high-frequency modulation signal modulated in this way is routed to the radiation source or laser diode 11, i.e., the VCSEL laser, via an attenuator 26 and a so-called bias-tee calibration circuit 27 with an inductance 28 and a capacitor 29, in order to modulate the emitted laser radiation accordingly, as described above, “doubly”, so as to enable the desired coupling of at least two dark resonances. Also allocated to the laser 11 is a current driver 30 (constant current source), along with a temperature stabilization circuit 31 as well.

A servo circuit (electronic controller) 32 that can be connected via a switch S1 with the first lock-in amplifier 18 is used for tuning relative to two Zeeman-split dark resonances caused by an external magnetic field, for example. The output of the controller 32 is applied via an adding stage 33 to the tunable frequency generator 25, the output of which is connected not just to the ring mixer 22 via another adding stage 34, but also to a frequency counter 35, so as to determine the magnetic field B to be measured using equation (5). The frequency counter 35 is further connected to the oscillator 23, which is also connected with modulation frequency generator 36, whose output is connected with the lock-in amplifier 19, and can also be connected via a switch S3 with the RF generator 24, as will be explained in greater detail below. Additionally connected with this modulation frequency generator 36 is a processor or computer (not shown in any greater detail on FIG. 7), with which the measurement results, if necessary after having been processed, can be output on a display or printer.

The frequency counter 35 and modulation frequency generator 36 are supplied with the frequency (10 MHz) of the oscillator 24 as the reference time base. This ensures a high stability in the entire system. The modulation frequency generator 36 can also be a DDS (DDS—digital-data-synthesizer), which is controlled by the PC or microprocessor (not shown), and which constitutes the modulation source for the phase-sensitive detection via the lock-in amplifier 19.

Also provided for operation in a scan mode is a ramp generator 37, which can be connected via a switch S2 with the adding stage 33, wherein the low-frequency sidebands can be scanned and the dark resonances can be recorded in this operating mode, in which the switch S1 is open, as will be explained below. In the locked mode, in which switch S1 is closed and switch S2 is open, the LF sidebands are coupled with the Zeeman dark resonances.

Finally, FIG. 7 also reveals that the second adding stage 34 is connected with a second input to a voltage source 38. The output of the mixer 22 is also connected via an isolator 39 with a terminating resistor 40 to the attenuator 26. The second lock-in amplifier 20 is connected to a frequency multiplier 41, and can be connected via a switch S4 with another servo circuit or controller 42, to which the RF generator 24 is connected.

How the measurement device according to FIG. 7 operates will now be explained in detail below. For reasons of systematics, let reference be made in advance to the signal at the output of the adding stage 33, which is comprised of the modulation signal Em(t) of the modulation generator 36

$${E}_{M} ( t ) = \frac{1}{2} {E}_{m} exp [ {iω}_{n} t ] + c . c . \qquad ( 10 )$$

on the one hand and the signal Eᵣₐₘₚ of the ramp generator 37 Eᵣₐₘₚ, or (depending on the setting of the switch S1 and S2) of the control signal Est of the electronic controller 32. The resulting overall signal

$${E}_{M} ( t ) = \frac{1}{2} {E}_{m} exp [ {iω}_{m} t ] + c . c . + E ( t ) \qquad ( 11 )$$

represents the modulation signal, with which the tunable frequency generator 25 is modulated. The term E(t) in equation 11 is to be equated with Eᵣₐₘₚ or Eₛₜ, depending on the switch setting of S1 and S2. To calculate the modulated output signal E₃(t) of the generator 25, the instantaneous phase must be formed through integration from the instantaneous angular frequency. The following relationship is therefore obtained for this output signal E₃(t):

$${E}_{3} ( t ) = \frac{1}{2} {E}_{0} exp [ i ( ω t + {k}_{F M} {\int }_{0}^{t} Re \{ {E}_{M} ( τ ) \} d τ + {φ}_{0} ) ] + c . c . \qquad ( 12 )$$

The angular frequency ω represents the center frequency of the generator 25 at Eₘ=0; φ₀ is the initial phase angle at τ=0.

In the case of a closed control loop 18 (switches S1 and S2 are open) and assuming stationary conditions, the analytical form of the output signal of the tunable frequency generator 25 is obtained as follows (when executing integration with equation 11 as the integrand):

$$\begin{matrix}{E}_{3} ( t ) = \frac{1}{2} {E}_{0} exp [ i ( {ω}_{0} t + β sin ( {ω}_{m} t ) ) ] + c . c . \\ = \frac{1}{2} {E}_{0} {\sum }_{n = - ∞}^{+ ∞} {J}_{n} ( β ) exp [ i ( {ω}_{0} + n {ω}_{m} ) t ] + c . c .\end{matrix} \qquad ( 13 )$$

In this equation (13), the Bessel functions of order n are indicated with Jₙ(β). Variable β is the modulation index, and here defined by the correlation β: =Δω/ωₘ=k_{FM}Eₘ/ωₘ. This variable β is a measure for the maximum deviation in instantaneous frequency from the center frequency relative to the modulation frequency ωₘ.

FIG. 8 shows a schematic view of the spectrum of frequencies at the output of the tunable frequency generator 25 under stationary conditions (locked-in state). The arrow pointing in a negative n-direction for the sideband ω₀−ωₘ symbolizes a phase shift of π relative to the carrier frequency ω₀. Sidebands of the order n≧±2, or ω₀ 2ωₘ, are not taken into account during further analysis given their low amplitude.

For the sake of simplicity, a modulation index of β≦1 will be assumed in the following. In this range, the signal-to-noise ratio is optimal. This approximation simplifies the mathematical derivation of corresponding expressions, since only the frequency components n=0, ±1 are considered. It be noted that conclusions relative to the occurrence of the corresponding signals of dark resonances also remain valid at specific frequency values for the case of β>1.

An open switch S1 and closed switch S2 yields a scanning mode of operation, which enables the recording of the entire dark resonance spectrum. The ramp-shaped (or triangular) signal of the ramp generator 37 (see FIG. 9A) in conjunction with the modulation signal of the modulation generator 36 (see FIG. 9B) triggers a constant increase over time (accompanied by simultaneous wobbling) of the instantaneous frequency of the tunable frequency generator 25. (The modulation generator 36 produces the wobbling at a frequency of ωₘ). The analytical form of the output signal E₃(t) of the tunable frequency generator 25 reads as follows under these preconditions:

$$\begin{matrix}{E}_{3} ( t ) = \frac{1}{2} {E}_{0} exp [ i ( {ω}_{0} t + β sin ( {ω}_{m} t ) + {k}_{F M} {\int }_{0}^{t} {E}_{Ramp} ( τ ) d τ ) ] + c . c . \\ = \frac{1}{2} {E}_{0} exp [ i {k}_{F M} {\int }_{0}^{t} {E}_{Ramp} ( τ ) d τ ] \cdot \\ {\sum }_{n = - ∞}^{+ ∞} {J}_{a} ( β ) exp [ i ( {ω}_{0} + n {ω}_{m} ) t ] + c . c .\end{matrix} \qquad ( 14 )$$

In equation 14, the (real-value) function Eᵣₐₘₚ with Eᵣₐₘₚ (τ)=Aᵣₐₘₚ·τ\/τε[0, T] delivers a linearly rising signal in the interval [0, T], which {periodically continued} yields the desired ramp-shaped signal progression (see FIG. 9A).

The functional form of the signal Eᵣₐₘₚ(τ) is not limited to a (linear) ramp signal. However, the linearly rising ramp signal simplifies the mathematical expression for instantaneous frequency

$$ω ( t ) = \frac{d}{d t} φ ( t ) = {ω}_{0} + {βω}_{m} cos ( {ω}_{m} t ) + {k}_{F M} \frac{\partial }{\partial t} {\int }_{0}^{t} {E}_{Ramp} ( τ ) d τ \qquad ( 15 )$$

of the tunable frequency generator 25. After the photodiode signal has been demodulated (see detector unit 17 on FIG. 7) by the lock-in amplifier 19, the (with respect to time) linear member in equation 15 can be used to establish a clear correlation between the frequency of the sidebands n·ωₘ and the instantaneous output signal of the ramp generator 37.

Shown in detail on FIG. 9 is the ramp-shaped signal of the ramp generator 37 (FIG. 9A), the summation signal comprised of the ramp signal and modulation signal of the modulation generator 36 (FIG. 9B) and the output signal of the tunable frequency generator 25 during frequency modulation with the summation signal (FIG. 9C). The parameters (amplitudes, modulation index, time axis) are selected in such a way as to provide a clear overview. The typical time scale on FIG. 9 is in ms. The typical ratio of VCO (25) fundamental frequency/VCO modulation frequency ranges from 5 . . . 10000.

Also shown on FIGS. 10A and 10B of FIG. 10 are the input signal E₃(t) and the output signal E₄(t) of the high-frequency mixer 22 with (FIG. 10B) and without (FIG. 10A) direct voltage share E_{D} as a function of time. In this case, the ratio of frequencies ω_{R}/ω₀=100 (instead of approx. 4000) was selected to provide a clear overview. The characteristic time scale depends on the magnetic field to be measured, and ranges between approx. ms . . . μs.

As evident from FIG. 4 and the accompanying description, the frequency components ν_{HFS} and ν_{±2ges} are required for coupling the dark resonances n=0 and n=±2. These frequency components can be generated simultaneously during a mixing process of the output signal of the tunable frequency generator 25 with the signal of the radio frequency synthesizer 24. This mixing process involves a multiplicative operation, which is carried out in the high-frequency mixer 22. The adding unit 34 and E_{D} voltage source 38 can be used to append a direct voltage component E_{D} to the output signal E₃(t) of the tunable frequency generator 25 (see also FIG. 10B). Depending on the height of E_{D}, this measure makes it possible to control the amplitude of the carrier frequency ω_{R}=2π·ν_{HFS}/2 in the microwave range. Therefore, the signal E₄(t) arises at the output of the mixer 22 as follows:

$${E}_{4} ( t ) = \frac{1}{2} ℳ {E}_{0} {E}_{2} {\sum }_{n = - ∞}^{+ ∞} {J}_{n} ( β ) exp [ i ( \begin{matrix}{ω}_{R} \pm \\ ( {ω}_{0} + n {ω}_{m} )\end{matrix} ) t ] + \frac{1}{2} ℳ {E}_{D} {E}_{2} exp [ {iω}_{R} t ] + c . c . \qquad ( 16 )$$

(Variable M here takes into account the characteristics of the mixer 22.)

For example, if E_{D}=0 is selected (see FIG. 10A), the carrier frequency disappears. In this way, only the magnetic field-dependent dark resonances n=±2 are coupled by the frequency components ν_{±2}. This case is assumed during the locked-in state (measurement operating state), i.e., when the switch S1 is closed and the switch S2 is open. The dark resonance n=0 independent of the magnetic field is no longer excited owing to the absent carrier frequency.

By contrast, the selection E_{D}≠0 makes it possible to tune the oscillator 24 precisely to the frequency ω_{R}=2π·ν_{HFS}/2. In this operating state (and only in this one), the oscillator 24 can only still be modulated via the modulation generator 36, i.e., the switch S3 is closed. This operating state of the magnetometer is only assumed when the frequency of the oscillator 24 is tuned to the frequency ω_{HFS}.

The isolator (circulator) 39 is a transmission-unsymmetrical 3-port with the property of further relaying the incoming electromagnetic waves to the next respective port (=terminal) (1-2-3).

As a consequence, the isolator 39 operates in such a way that the reflected wave as shown on FIG. 7 caused by an electrical maladjustment of the VCSEL laser diode 11 is relayed in the isolator 39 counterclockwise (in the direction of the arrow) to the terminal resistor 40, where it is completely absorbed. This prevents this reflected wave from getting to the mixer 22, and there interfering with the advancing (toward the VCSEL laser diode 11) wave field or with E₃(t).

The overlapping of the signal E₄(t) and supply current (coming from the constant current source 30) necessary for operating the VCSEL 11 arises at the junction between the inductor 28/capacitor 29 and VCSEL laser diode 11.

The necessary separation of the microwave signals and supply current of the VCSEL 11 is achieved via the inductor 28 and capacitor 29 contained in the bias tee 27.

The capacitor 29 of the bias tee 27 protects the microwave signal path against the direct voltage on the VCSEL diode 11, which arises during operation owing to the applied supply current. This counteracts a saturation of the mixer 22 by this identical level. On the other hand, the inductor 28 of the bias tee 27 uses a low-pass effect to ensure that no microwave signals can advance toward the constant current source. The outward radiation of these microwave signals is thereby prevented.

Among other things, the high-frequency modulation of the applied supply current of the VCSEL diode causes known periodic changes in the refraction index in the laser medium (not shown in any greater detail) in the laser resonator. These periodic changes result directly in an amplitude and frequency modulation of the emitted laser radiation:

$$\begin{matrix}\begin{matrix}{E}_{6} ( t ) = \frac{1}{2} {E}_{L} exp [ i ( {ω}_{L} t + {k}_{γ} {\int }_{- ∞}^{t} {E}_{4} ( τ ) d τ ) ] + c . c . \\ = \frac{1}{2} {E}_{L} exp [ i ( \begin{matrix}{ω}_{L} t + {k}_{γ} ℳ {E}_{ 0} {E}_{2} {\sum }_{n = - ∞}^{+ ∞} \frac{{J}_{n} ( β )}{{\tilde{ω}}_{n}} sin ( {\tilde{ω}}_{n} ) + \\ \frac{{k}_{γ} ℳ {E}_{D} {E}_{2}}{{ω}_{R}} sin ( {ω}_{R} t )\end{matrix} ) ] + c . c . \\ = \frac{1}{2} {E}_{L} {\sum }_{j = - ∞}^{+ ∞} {J}_{j} ( C ) exp [ i ( {ω}_{L} + {jω}_{R} ) t ] \cdot \\ {\prod }_{n = - ∞}^{+ ∞} {( {\sum }_{l = - ∞}^{+ ∞} {J}_{t} ( {B}_{n} ) exp [ i t {\tilde{ω}}_{n} t ] )}_{n} + c . c .\end{matrix} & ( 17 ) \\ with \\ {B}_{n} := {k}_{γ} ℳ {E}_{0} {E}_{2} \frac{{J}_{n} ( β )}{{\tilde{ω}}_{n}} \\ C := {k}_{γ} \frac{ℳ {E}_{D} {E}_{2}}{{ω}_{R}} \\ {\tilde{ω}}_{n} := {ω}_{R} \pm ( {ω}_{0} + n {ω}_{m} ) \\ β := \frac{{k}_{F M} {E}_{m}}{{ω}_{m}} \\ {E}_{L} := ( \begin{matrix}{E}_{x} \\ {E}_{y} {e}^{i φ}\end{matrix} ) exp [ i {k}_{0} z ] & \end{matrix}$$

The vector of the electric field strength E_{L} (of the laser radiation) indicates the polarization state. The size of the modulation constant k_{γ} depends on the working point of the VCSEL.

The multichromatic laser field immediately after the VSCEL source is given by equation 17, save for the omission of a small amount of amplitude modulation by the nonlinear characteristic of the VCSEL 11. The approximation of small modulation indices (Bₙ, C˜=1) illustrates more clearly that, given a suitable selection of frequency ω_{L} (optical range) and modulation frequencies (ω_{R}, ω₀ and ωₘ), all frequencies required for coupling the dark resonances are contained in equation 17. In addition, this approximation can also be used to correctly describe the real operating state of the magnetometer device, since the selection of Bₙ, C˜=1 largely avoids the non-resonant, higher harmonic frequency components (j, 1≧±2). (This does not hold true for modulation index β, for which higher harmonic portions are also of importance (especially n=±2).) In this approximation, equation 17 is simplified to:

$${E}_{6} ( t ) = \frac{1}{2} {E}_{L} [ \begin{matrix}\begin{matrix}{J}_{- 1} ( C ) {e}^{i ( {ω}_{L} - {ω}_{R} ) t} + \\ {J}_{0} ( C ) {e}^{{iω}_{L} t} +\end{matrix} \\ {J}_{+ 1} ( C ) {e}^{i ( {ω}_{L} + {ω}_{R} ) t}\end{matrix} ] \cdot ( 1 + \frac{1}{2} {\sum }_{n = - ∞}^{+ ∞} {B}_{n} ( \begin{matrix}{e}^{i {\tilde{ω}}_{n} t} - \\ {e}^{- i {\tilde{ω}}_{n} t}\end{matrix} ) ) + c . c . \qquad ( 18 )$$

During magnetometer operation, a distinction is made between the pre-stabilization of the RF synthesizer 24 and the actual “measurement mode”. In the first case (with switch S3 closed), E₀=0 makes all coefficients Bₙ=0. Therefore, only harmonic components j·ω_{R} (see equation 17) arise around the frequency of the optical transition ω_{L}, including the sidebands n·ωₘ arranged around ω_{L}+j·ω_{R} (|j|>0). The sidebands are required for generating the error signal of pre-stabilization. Let it be noted that the additional modulation of the RF synthesizer 24 in this operating state is not taken into account in equation 17 for reasons of clarity. Another product term (compare equation 17) would be added from the mathematical structure.

This operating state will not be further discussed below, since this pre-stabilization only sets in when the RF synthesizer 24 exhibits an (actually impermissible) deviation.

During the measurement of external magnetic fields, parameters E_{D}=0 or C=0 are set (switch S3 is open, switch S1 is closed). Equation 18 is therefore again simplified to read:

$$\begin{matrix}{E}_{6} ( t ) = \frac{1}{2} {E}_{L} {J}_{0} ( C ) \cdot \\ ( {e}^{{iω}_{L} t} + \frac{1}{2} {\sum }_{n = - ∞}^{+ ∞} {B}_{n} ( {e}^{i ( {ω}_{L} + {\tilde{ω}}_{n} ) t} - {e}^{i ( {ω}_{L} - {\tilde{ω}}_{n} ) t} ) ) + c . c . \\ = \frac{1}{2} {E}_{L} {J}_{0} ( C ) \cdot \\ ( {e}^{{iω}_{L} t} + \frac{1}{2} {\sum }_{n = - ∞}^{+ ∞} {B}_{n} ( \begin{matrix}{e}^{i ( {ω}_{L} + {ω}_{R} \pm ( {ω}_{0} + n {ω}_{m} ) ) t} - \\ {e}^{i ( {ω}_{L} - {ω}_{R} ∓ ( {ω}_{0} + n {ω}_{m} ) ) t}\end{matrix} ) ) + c . c .\end{matrix} \qquad ( 19 )$$

As very readily evident from equation 19, both the frequency components ω_{L}+ω_{R}±(ω₀+nωₘ) and ω_{L}−ω_{R}∓(ω₀+nωₘ) (with n=0) for coupling all dark resonances are present, as are all frequency components ω_{L}+ω_{R}±(ω₀+nωₘ) and ω_{L}−ω_{R}∓(ω₀+nωₘ) (with n≠0) for the phase-sensitive detection by the lock-in amplifier 19.

The transversal mode structure of the electromagnetic field E₆ of a VCSEL corresponds to the Gaussian 0-0 mode owing to the geometric dimensions of the active medium The transversal intensity profile hence follows a Gaussian function. A polarization state can clearly be assigned to the laser field. In the case of a VCSEL laser, the emitted electromagnetic wave is linearly polarized to a large extent. The electromagnetic field E₆ of equations 17 to 19 can be set up as a Jones vector

$${E}_{6} ( t ) = ( \begin{matrix}{E}_{x} ( t ) \\ {E}_{y} ( t ) {e}^{iφ}\end{matrix} ) \approx \frac{{E}_{L} ( t )}{\sqrt{2}} ( \begin{matrix}1 \\ 1\end{matrix} ) \qquad ( 20 )$$

For example, a largely linear polarization state of E₆(t) with the polarization plane 45° toward the x-direction is characterized by Eₓ=E_{y} and φ=n·π, nεN₀ (see last expression in equation 20).

The formation of Λ-shaped excitation schemes (see FIG. 4) and the coupling thereof is possible with a linear, circular or generally polarized E₆-field. The polarization state of E₆ desired during magnetometer operation is set by the position of the primary axes of the λ/4 plate (QW on FIG. 7) relative to the components of E₆.

The transfer characteristic of the λ/4 plate QW is indicated by a 2×2 Jones matrix T̅ with (φ_{T}=±π/2):

$$\begin{matrix}{E}_{T} ( t ) = \overline{T} \cdot {E}_{6} ( t ) = \\ = ( \begin{matrix}1 & 0 \\ 0 & {e}^{{iφ}_{T}}\end{matrix} ) ( \begin{matrix}{E}_{6 x} ( t ) \\ {E}_{6 y} ( t ) {e}^{iφ}\end{matrix} ) \\ = ( \begin{matrix}1 & 0 \\ 0 & \pm i\end{matrix} ) ( \begin{matrix}{E}_{6 x} ( t ) \\ {E}_{6 y} ( t ) {e}^{iφ}\end{matrix} )\end{matrix} \qquad ( 21 )$$

Circular polarized light E₇ is generated (using equation 19) in cases where linear polarized light (E₆) is incident on the λ/4 plate with the polarization plane at an angle of 45° relative to the primary axes.

$${E}_{7} ( t ) = ( \begin{matrix}1 & 0 \\ 0 & \pm i\end{matrix} ) \frac{{E}_{L} ( t )}{\sqrt{2}} ( \begin{matrix}1 \\ 1\end{matrix} ) = \frac{{E}_{L} ( t )}{\sqrt{2}} ( \begin{matrix}1 \\ \pm i\end{matrix} ) \qquad ( 22 )$$

By contrast, linear polarized light E₇ arises when the polarization plane of E₆ coincides with one of the primary axes of the λ/4 plate. For example, a light polarized in the x-direction in turn arises for Eₓ=E_{L} and E_{y}=0 (φ=any value desired):

$${E}_{7} ( t ) = ( \begin{matrix}1 & 0 \\ 0 & \pm i\end{matrix} ) {E}_{L} ( t ) ( \begin{matrix}1 \\ 0\end{matrix} ) = {E}_{L} ( t ) ( \begin{matrix}1 \\ 0\end{matrix} ) \qquad ( 23 )$$

By contrast, an elliptically polarized, electromagnetic field E₇(t) is obtained given any selected angle for the polarization plane of the linearly polarized wave field E₆(t) with the primary axes of QW. This circumstance becomes evident from a mathematical standpoint when E₆ₓ≠E_{6y} and φ=n·π, n·εN₀ are set in equation 21.

Selecting the angle for the primary axis of the λ/4 plate QW relative to the polarization plane of the linearly polarized electromagnetic wave E₆(t) makes it possible to set the correspondingly desired polarization state of E₇(t) (linear, circular, elliptical). Which polarization state is the most suitable depends on a potentially present preferred direction of the (external) magnetic field to be measured, and on the propagation direction of E₇(t).

For example, maximum sensitivity in a magnetic field B is achieved in a (normal to the) propagation direction of E₇(t) when a circular (linear) polarization of E₇(t) is selected.

The electromagnetic field E₇(t) then begins to interact with the atom ensemble in the measurement cell 14. The semi-classic access (no quantized electromagnetic field) via the so-called density matrix formalism is here selected for describing the quantum mechanical processes of a (statically distributed) atom ensemble (e.g., alkali atom vapor). In order to take spontaneous decay mechanisms into account (e.g., relaxation from the excited state to the ground state, relaxation as the result of collisions, etc.), phenomenological additional terms R(t) (called relaxation operator) are appended in the density matrix equations:

$$\frac{d}{d t} \hat{p} ( t ) = \frac{1}{i ℏ} [ \hat{ℋ} ( t ) , \hat{p} ( t ) ] + \hat{R} ( t ) \qquad ( 24 )$$

In this equation 24, the Hamilton operator H=Hₒ+V(t) consists of the Hamilton operator Ĥ₀ of the undisturbed atom, as well as a time-dependent (disturbance) term \hat{V}(t), which describes the interaction with the electromagnetic fields. This interaction term reads as follows in the dipole approximation (λₒₚₜ>>τ_{Bohr}):

\hat{V}(t)=−\hat{d}·E(t) (25)

The variable \hat{d} relates to the examined dipole moment of the atomic transition. The coupling of the atomic system of the ensemble with the electromagnetic field takes place according to equation 25, if E(t)=E₇(t) is set.

In component form, equation 24 reads as follows for N levels:

$$\frac{d}{d t} {ρ}_{ij} ( t ) = - i {ω}_{ij} {ρ}_{ij} ( t ) + \frac{1}{i h} {\sum }_{k = 1}^{N} [ {V}_{ik} ( t ) {ρ}_{kj} ( t ) - {ρ}_{ik} ( t ) {V}_{kj} ( t ) ] + {R}_{ij} ( t ) \qquad ( 26 )$$

The dipole operator \hat{V}(t), which establishes the coupling with the multichromatic laser field (equation 17 or equation 21), reads as follows in this component representation:

Vᵢⱼ(t)=−dᵢⱼ·E₇(t) (27)

The differential equation system (equation 26 with the multichromatic laser field E₇(t) according to equation 27) generally represents a very complicated system, which most often has more than 250 unknown variables within the alkali D lines. The solution to this mathematical problem can only be found numerically in this generality.

One way to yet obtain approximated analytical expressions for variables ρᵢⱼ lies in the assumption that the line width of the dark resonances is small by comparison to the splitting of the Zeeman sub-level. Under these circumstances, the degeneration of the various levels is eliminated. The atomic levels (equation system 26) are decoupled from each other in terms of excitation by the field E₇(t) in such a way as to yield an excitation scheme of the kind on FIG. 4, wherein a single-photon transition between 5²S_{1/2}F=2, m_{F}=−2→5²S_{1/2}F′=2, m_{F}=−1 additionally arises. This makes it possible to reduce the complicated system of equation 26 to three Λ-systems, which “only” are coupled via the incoherent process of spontaneous decay (by \hat{R}(t)).

The solutions to the density matrix equations in the known RWA approximation (RWA—rotating wave approximation) are for Λ-systems plus a loss level that describes the remaining incoherent coupling.

The variable ρₙₙ(t) indicates the (percentage) share of the atoms in the statistical ensemble in state n.

The variables ρₙₘ(t)=σₙₘ(t) exp[iωₙₘ] are referred to as coherences. The real portion and imaginary portion of the coherences (ρₙₘ(t) and σₙₘ(t)) of the optical transitions are functionally correlated with the refraction index and attenuation index of the medium (atom ensemble).

Given as an example is the solution for coherences ρ₁₃ of the stationary density matrix. The solutions are all indicated as a series of Lorentz functions L^{abs}ᵢ and L^{diss}ᵢ.

$$Re ( {σ}_{i 3} ) = \frac{{}_{i}^{ }{𝒜}{}_{0}^{0} {δ}_{R}}{{δ}_{R}^{2} + {( \frac{Δ v}{2} )}^{2}} + [ \frac{{}_{i}^{}{𝒜}{}_{1}^{1} {δ}_{R}}{{δ}_{R}^{2} + {( \frac{Δ v}{2} )}^{2}} + \frac{{}_{i}^{}{𝒜}{}_{2}^{1} {δ}_{R}}{{( {δ}_{R}^{2} + {( \frac{Δ v}{2} )}^{2} )}^{2}} + \frac{{}_{i}^{}{𝒜}{}_{3}^{1}}{{δ}_{R}^{2} + {( \frac{Δ v}{2} )}^{2}} ] {δ}_{L} \\ Im ( {σ}_{i 3} ) = \frac{{}_{i}^{}{ℬ}{}_{0}^{0}}{{δ}_{R}^{2} + {( \frac{Δ v}{2} )}^{2}} + [ \frac{{}_{i}^{}{ℬ}{}_{1}^{1} {δ}_{R}}{{δ}_{R}^{2} + {( \frac{Δ v}{2} )}^{2}} + \frac{{}_{i}^{ }{ℬ}{}_{2}^{1} {δ}_{R}}{{( {δ}_{R}^{2} + {( \frac{Δ v}{2} )}^{2} )}^{2}} ] {δ}_{L} \qquad ( 28 )$$

The function L^{abs}ᵢ (L^{diss}ᵢ) is symmetrical (skew symmetrical) relative to the Raman detuning δ_{R}.

The parameters ᵢA^{l}ₖ and ᵢB^{l}ₖ depend on the field strength E₁ and the dipole matrix elements dₙₘ. The two-photon detuning δ_{L} in equation 28 triggers a deviation from a pure Lorentz function L^{abs} ᵢ (L^{diss}ᵢ) However, this influence is of a higher order (ᵢA^{l}ₖ δ_{L}/ᵢA⁰₀<<1, ᵢB^{l}ₖδ_{R}δ_{L}/ᵢB⁰₀<<1, and for corresponding k, l (ᵢA^{l}ₖ δ_{L}/ᵢA⁰₀δ_{R}<<1), when δ_{L}<δ_{doppler}≈500 MHz is observed. Laser stabilization to the corresponding atomic transition yields a maximum two-photon detuning of |δ_{L}|≦10 MHz. Raman detuning δ_{R} in equation 28 is the actual magnetic field-dependent variable, and can be identified as a function of the respectively observed Λ-system (n=−2, 0, +2) with δ_{R-2}, δ_{R0} and δ_{R+2}. FIG. 2 provides a graphic representation of Re (σ₁₃) and Im (σ₁₃) under the condition (δ_{L}<δ_{doppler}).

In order to establish these functional correlations between coherences σₙₘ and the real or imaginary part of the susceptibility χ=χ′+iχ″ of the medium (=atomic vapor), the results of electrodynamics are drawn upon:

P(z,t)=N_{act}Tr(\hat{d}\hat{ρ}) (29)

P(z,t)=(χ′+iχ″)E(z,t) (29)

Herein, N_{act} refers to the molar density of the atoms in the gaseous state.

For specific calculations, polarization P(z,t) is handled after broken down into its constituent components. In order to correctly consider the Doppler effect, the density matrix elements must also be averaged for all speeds (weighted for the prevailing speed distribution (most often Maxwell distribution)).

$${P}_{sm} = {N}_{act} \vert {e}_{sm} {d}_{ms} \vert {\tilde{σ}}_{sm} \\ {\tilde{σ}}_{sm} = {\int }_{- ∞}^{+ ∞} d {v}_{z} {σ}_{sm} ( {v}_{z} ) w ( {v}_{z} ) \qquad ( 30 )$$

Equations 29 and 30 can be successfully used to establish a connection between the microscopic (quantum mechanical) variables and the observable macroscopic variables (susceptibilities) (when observing an Λ-system):

$${χ}^{′} ( {ω}_{j} ) = \frac{{N}_{act}}{{E}_{j}} {d}_{3 j} Re ( {σ}_{j 3} ) \\ {χ}^{″} ( {ω}_{j} ) = \frac{{N}_{act}}{{E}_{j}} {d}_{3 j} Im ( {σ}_{j 3} ) \qquad ( 31 )$$

For example, the atomic vapor measurement cell 14 of the magnetometer operates in a temperature range of up to 50° C. (rubidium). Under these operating conditions, the atomic vapor can still be regarded as optically thin. Only simple scatterings of photons on the atoms take place in this range, thereby establishing the validity of the Beer-Lambert law of attenuation:

$$E ( t , L ) = \frac{1}{2} {\sum }_{j = 1}^{n} {E}_{j} ( t , 0 ) exp [ {iω}_{j} t ] exp [ i {k}_{j} L ( 1 + ( {χ}^{′} ( {ω}_{j} ) + {iχ}^{″} ( {ω}_{j} ) 0 / 2 ) ) ] + c . c . \qquad ( 32 )$$

In addition to exponential attenuation, the influence of x′ gives rise to a phase shift that grows linearly with the optical path. This is a direct consequence of the refraction index differing from one.

In order to facilitate use of the equations and provide better clarity, the functional correlations of relevance for propagation will be combined into a propagation operator F.

$$\begin{matrix}\begin{matrix}{E}_{j} ( t , L ) = \frac{1}{2} {E}_{j} ( t , 0 ) exp [ i ( {k}_{j} L + {ω}_{j} t ) ] \\ exp [ i ( {𝒳}^{′} ( {ω}_{j} ) + {iχ}^{″} ( {ω}_{j} ) ) / 2 ] + c . c . \\ = \frac{1}{2} {F}_{j} {E}_{j} exp [ i ( {k}_{j} L + {ω}_{j} t ) ] ] + c . c .\end{matrix} & ( 33 ) \\ {F}_{j} := exp [ - {δ}_{j} - {iφ}_{j} ] \\ {δ}_{j} := \frac{{k}_{j} L}{2} {χ}^{″} ( {ω}_{j} ) \\ {φ}_{j} := - \frac{{k}_{j} L}{2} {χ}^{′} ( {ω}_{j} ) & \end{matrix}$$

This operator has the nature of a vector, with components x and y, and the spectral components Fⱼ, which correspond to the respective ωⱼ.

Hence, the propagation operator Fⱼ describes the interaction between the electromagnetic fields and the atom ensemble. The index of the propagation operator refers to the spectral component ωⱼ, to which the operator is applied. The variable L denotes the (geometric) length of the optical path, and can here be simultaneous with the length (in the cm range) of the spectroscopic measurement cell 14.

Applying the propagation operator Fⱼ to the multichromatic wave field E₇(t) arising at the input of the spectroscopic measurement cell 14 yields the multichromatic wave field E₈(t) immediately after the cell 14 as follows:

$$\begin{matrix}{E}_{8} ( t , L ) = \hat{F} \cdot {E}_{7} ( t ) \\ = \frac{1}{2} {E}_{7} {\sum }_{j = - ∞}^{+ ∞} {F}_{j} {J}_{j} ( C ) exp [ i ( {ω}_{L} + {jω}_{R} ) t ] \cdot \\ {\prod }_{n = - ∞}^{+ ∞} {( {\sum }_{l = - ∞}^{+ ∞} {F}_{l} {J}_{1} ( {B}_{n} ) exp [ i l {\tilde{ω}}_{n} t ] )}_{n} + c . c .\end{matrix} \qquad ( 34 )$$

This wave field E₈(t) contains the complete information resulting from the interaction with the atomic vapor.

In addition to the various functional dependencies of the parameters specified above (for example, see equations 17 and 34), the functional dependence of the frequency ω0 of the tunable frequency generator 25 proves to be the most important. This frequency ω0 is variable in the sense that it is varied until such time as the dark resonances n=−2, 0, +2 coincide in a single (observable) dark resonance. In a manner of speaking, this frequency bridges the splitting of the magnetic sub-level caused by the Zeeman effect (see equation 3). If the frequency ω0 corresponds with the Zeeman splitting frequency, a level degeneration is formally established. The Λ-shaped excitation schemes are coupled under these circumstances. Therefore, the signal E8(t,L) (the signal form in the time range) depends significantly on the value ω0 relative to the atomic sub-levels. If E8(t,L) enables this information, the control technology related problem, specifically tuning the tunable oscillator 25 precisely to this sub-level splitting, can be resolved. In order to achieve this, the general multichromatic wave field is converted by the photodetector 15 into an electrical signal. A photodetector is a so-called quadratic element, in which the electrical signal, the photoelectric current iph(t), is proportional to the arising intensity (power) of the electromagnetic radiation:

$${i}_{ph} ( t ) = {ℛ}_{ph} ( λ ) {P}_{8} ( t ) = {ℛ}_{ph} {\int }_{A} {I}_{8} ( t , L ) d A = \frac{{ℛ}_{ph}}{{Z}_{vac}} {G}_{L} {E}_{8}^{2} ( t , L ) \qquad ( 35 )$$

The variable Rₚₕ(λ) is referred to as the photodiode responsiveness; Z_{vac} is the wave resistance of the vacuum.

The integration according to equation 35 is performed throughout the entire intensity profile. The value of constants G_{L} depends on the specific form of the intensity progression as a function of the local coordinates (transverse to the laser propagation direction). In all of the deliberations pursued here, the largest value for the transverse profile can therefore be set for the electrical field strengths E₁ (the local dependence is then incorporated in G_{L}). The process of squaring represents a complication with respect to mathematical analysis, since mixed terms also arise for the sums and differential frequencies given the infinite variety of frequency components.

However, a further simplification is achieved by taking into account the fact that the used photodetector 15 cannot register frequencies in the optical range (˜1014 Hz) in time-resolved manner.

E₈²(t,L)=(|E₈²|+|E₈*²|+2E₈E₈*)=2E₈E₈*+const. (36)

The second equal sign in equation 36 is valid since the summands |E28| and |E8*2| are periodic functions of time with a frequency of 2ωL˜1014 rad/s, and the photodetector 15 only registers their average value owing to its low-pass effect. The (chronologically) constant value const. need no longer be taken into account due to the phase-sensitive detector of the photodiode signal. The evaluation of the mixed term 2E8E*8 of equation 36 yields a signal proportional to the photodetector current, which is important for the further evaluation. While calculating the mixed term, the multichromatic electromagnetic field is used in the form of equation 19 in conjunction with the propagation operator F.

$${E}_{8}^{2} ( t , L ) = 2 {J}_{0}^{2} ( C ) {\vert {E}_{L} \vert}^{2} {F}_{L} {F}_{L}^{*} ( \begin{matrix}1 + \frac{1}{2} {\sum }_{n = - ∞}^{+ ∞} {\vert {F}_{n} \vert}^{2} {B}_{n}^{2} - \\ \frac{1}{2} {\sum }_{n = - ∞}^{+ ∞} {\vert {F}_{n} \vert}^{2} {B}_{n}^{2} cos 2 {\tilde{ω}}_{n} + \\ \frac{1}{2} {\sum }_{k = - ∞}^{+ ∞} {\sum }_{l = - ∞}^{+ ∞} {B}_{k} {B}_{l} ( \begin{matrix}ℜ [ {F}_{k} {F}_{l}^{*} ] cos ( {ω}_{k} - {ω}_{t} ) t - \\ [ {F}_{k} {F}_{l}^{*} ] sin ( {ω}_{k} - {ω}_{t} ) t\end{matrix} ) - \\ \frac{1}{2} {\sum }_{k = - ∞}^{+ ∞} {\sum }_{l = - ∞}^{+ ∞} {B}_{k} {B}_{l} ( \begin{matrix}ℜ [ {F}_{k} {F}_{l}^{*} ] cos ( {ω}_{k} + {ω}_{t} ) t + \\ [ {F}_{k} {F}_{l}^{*} ] sin ( {ω}_{k} + {ω}_{t} ) t\end{matrix} )\end{matrix} ) \qquad ( 37 )$$

(Therein, R[ . . . ] or I { . . . } mean real part of [ . . . ] or imaginary part of [ . . . ].)

The functional correlation (equation 37) describes the entire dark resonance spectrum (the coupled dark resonances) during excitation of the multichromatic laser field in the approximation of small modulation indices (Bₙ, C 1) ≈ under the pre-condition that the detector 17 cannot detect the frequency components of the electrical field lying in the optical range in a time resolved manner. The equation 37 is typical for the principle of coupling dark resonances at the measurement of magnetic fields with the aid of the CPT (Coherent Population Trapping) effect. From this combined signal, the portions most suitable for the operation of the magnometer must be extracted.

Due to the power level of P=1 . . . 10 μW, the unit 17 (photodetector 15 and amplifier 16) can only register frequency shares of the signal iₚₕ(t) in a time resolved manner up to a maximum of several MHz. The frequency components in the GHz range are therefore no longer present at the input of the lock-in amplifier 19.

A voltage proportional to the photoelectric current of the photodetector 15

$${u}_{8} ( t ) = \ddot{U} ( ω ) {R}_{T} {i}_{ph} ( t ) = \frac{{ℛ}_{ph}}{{Z}_{vac}} \ddot{U} ( ω ) {R}_{T} {G}_{L} {E}_{8}^{2} ( t , L ) \qquad ( 38 )$$

is given at the output of the detector unit 17 (proportionality is established via the transimpedance RT and the (overall) transfer function U (ω) of the unit 17); this voltage is itself (except for the high-frequency shares (see above)) proportional to the signal E₈(t,L). The task of the lock-in amplifier 19 is now to select the frequency components of u₈(t) suitable for magnetometer operation. The pre-factors for the frequency components incorporate the required information about the strength of the outer magnetic field in the form of the refraction (δⱼ) and attenuation (φj) index of the dark resonances. Based on equation 37, the frequency components

$${u}_{8} ( t ) = \frac{1}{2} {J}_{0}^{2} ( C ) \frac{{ℛ}_{ph}}{{Z}_{vac}} {R}_{T} {G}_{L} {\vert {E}_{L} \vert}^{2} {ɛ}^{- 2 {δ}_{L}} \cdot ( \begin{matrix}1 + {\sum }_{j = - ∞}^{+ ∞} {B}_{j}^{2} {e}^{- 2 {δ}_{j}} ++ {a}_{+ 1} {a}_{+ 2} {e}^{- 2 {δ}_{+ 2 + 2}} \cdot \\ ( \begin{matrix}- {δ}_{- 2 - 3} + {δ}_{- 2 - 1} + \\ {δ}_{+ 2 + 1} - {δ}_{+ 2 + 3}\end{matrix} ) cos {ω}_{m} t + \\ \begin{matrix}{a}_{+ 1} {a}_{+ 2} {e}^{- 2 {δ}_{+ 2 + 2}} \cdot \\ ( \begin{matrix}- {φ}_{- 2 - 3} + 2 {φ}_{2 - 2} - {φ}_{- 2 - 1} + \\ {φ}_{+ 2 + 1} - 2 {φ}_{+ 2 + 2} + {φ}_{+ 2 + 3}\end{matrix} ) sin {ω}_{m} t +\end{matrix} \\ \begin{matrix}{a}_{+ 1} {a}_{+ 3} {e}^{- 2 {δ}_{+ 2 + 2}} \cdot \\ ( \begin{matrix}- 2 - {δ}_{- 2 - 1} - 2 {δ}_{- 2 - 2} + {δ}_{- 2 - 3} + \\ {δ}_{+ 2 + 1} - 2 {δ}_{+ 2 + 2} + {δ}_{+ 2 + 3}\end{matrix} ) cos 2 {ω}_{m} t +\end{matrix} \\ {a}_{+ 1} {a}_{+ 3} {e}^{- 2 {δ}_{+ 2 + 2}} \cdot ( \begin{matrix}- {φ}_{- 2 - 3} - {φ}_{- 2 - 1} + \\ {φ}_{+ 2 + 1} - {φ}_{+ 2 + 3}\end{matrix} ) sin 2 {ω}_{m} t\end{matrix} ) \qquad ( 39 )$$

have proven suitable for magnetometer operation, wherein Ü(ω)=1+0 J was selected for improved clarity. Corresponding spectral representations are shown on FIGS. 11 to 14. Equation 39 uses other indices to enable a more compact notation of the equation. Indices ±1, ±2 and ±3 of equation 39 relate to the frequency components:

ω₋₃:=ω_{R}−ω₀−ωₘ

ω₋₂:=ω_{R}−ω₀

ω₋₁:=ω_{R}−ω₀+ωₘ

ω₀:=ω_{R}

ω₊₁:=ω_{R}+ω₀−ωₘ

ω₊₂:=ω_{R}+ω₀

ω₊₃:=ω_{R}+ω₀+ωₘ (40)

The indices n and j of δₙⱼ and φₙⱼ here relate to the n-th dark resonance (n=−2, 0, +2), which is generated by the j-th frequency component (j=−3 . . . +3).

The selection of expressions ˜ωₘ and ˜2ωₘ in equation 39 is achieved by using the orthogonality of trigonometric functions. Consequently, the technical realization of this selection takes place by multiplying u₈(t) by one (or more) sine/cosine oscillations, which exhibit the frequency cωₘ (c=1, 2) and the phase φ_{LockIn}. A subsequent filtering of all time-dependent shares ˜2ωₘ of u₉(t) yields an electrical signal u₉(t) proportional to the pre-factors of sin(cωt) and cos(cωt) (c=1, 2) (see also FIGS. 11 to 14). (The transfer function of the electronic filter (digital or analog) is labeled U_{L}.)

u₉(t)=Ü_{L}u₈(t)·u_{LockIn} sin(c·ωₘt+φ_{LockIn}) (41)

Whether this multiplication is realized using digital circuits (digital lock-in amplifiers 19) or, as sketched on FIG. 7, with an analog approach, is of subordinate importance. Both methods are prior art, and essentially lead to the same end result.

FIGS. 11 to 15 show the individual components of the signal u₉(t). Except for an additional factor that stems from the characteristic of the multiplication process, these signals correspond with the pre-factors of the terms sin(cωₘt) and cos(cωₘt) of equation 39. In these examples, the parameters for line width δν=50 Hz (see equation 28) and the frequency of the modulation frequency generator 36 are selected in such a way (νₘ=ωₘ/2π=2 kHz) as to correspond to typical values of a real magnetometer.

The independent variable is always the frequency ω₀ of the tunable generator 25. In the final analysis, this frequency is used to determine the magnetic field B through measurement by means of the frequency counter 35 and corresponding conversion. The control loop 18 of the magnetometer arrangement on FIG. 7 is set up in such a way (see below) as to ensure ω₀/2π=ν_{B}=C·B (see equation 5). In FIGS. 11 to 15, this point corresponds with the origin of the respective coordinate system. The frequency zero in the figures was hence expediently placed in the point ν_{B}=C·B, which corresponds with the position of the dark resonance given a concrete magnetic field measurement.

The amplitudes of the individual components are normalized to 1. As a consequence, the maxima for the overall signals ≧1. The frequency values on the abscissas on FIGS. 11 to 15 are indicated in kHz.

In particular, FIG. 11 shows the frequency modulation spectrum of the overall absorption signal (pre-factor to cos ωₘt; see equation 39) for the coupled dark resonances, wherein the detuning of the microwave generator 24 measures δν=0 Hz. FIG. 11A depicts a magnified area of the latter, wherein this detuning measures δν=0, 10, 25 or 50 Hz, so that four graphs are presented.

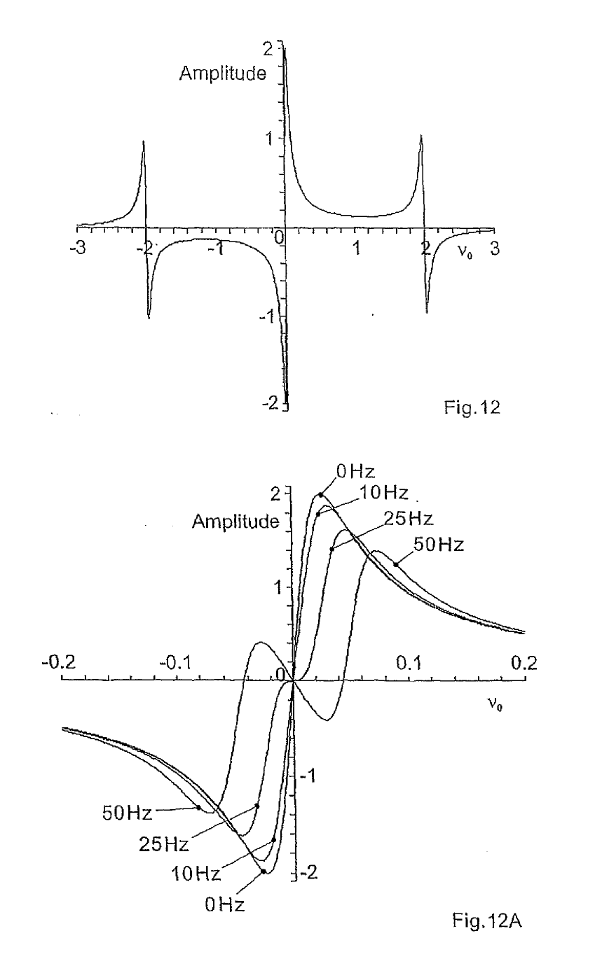

FIG. 12 shows the frequency modulation spectrum for the overall dispersion signal (pre-factor to sin ωₘt; see equation 39) of the coupled dark resonances, wherein the detuning of the microwave generator 24 measures δν=0 Hz. The depiction on FIG. 12A again shows a magnified area, wherein for curves are again presented for the detunings δν=0, 10, 25 or 50 Hz.

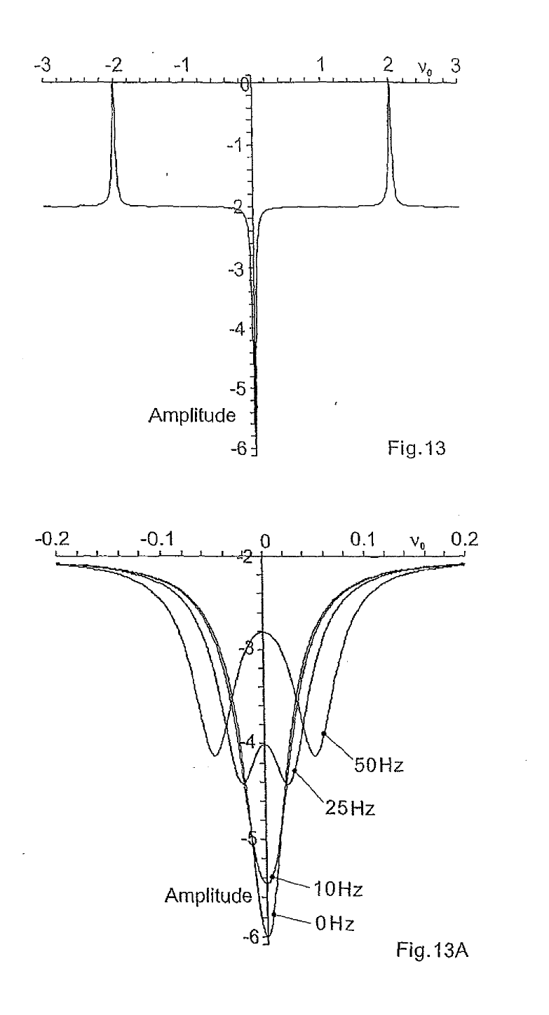

FIG. 13 illustrates the frequency modulation spectrum of the overall signal of the pre-factor to cos 2ωₘt (see equation 39) of the coupled dark resonances, wherein the detuning of the microwave generator 24 measures δν=0 Hz. FIG. 13A again depicts a magnified area, wherein four curves are represented for the detunings δν=0, 10, 25 or 50 Hz.

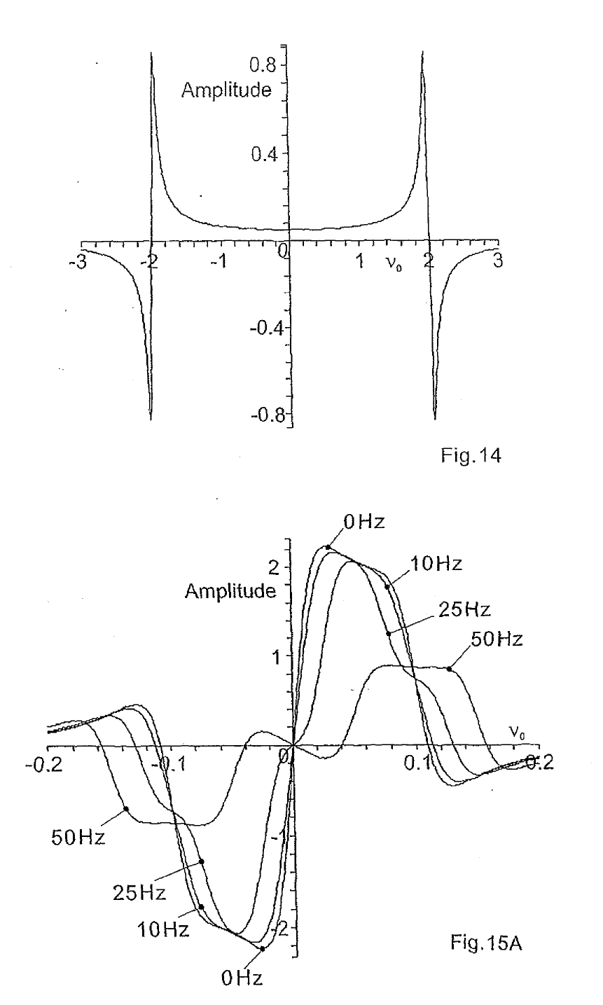

Then evident from FIG. 14 is the frequency modulation spectrum of the overall signal of the pre-factor to sin 2ωₘt (see equation 39) of the coupled dark resonances, wherein the detuning of the microwave generator 24 measures δν=0 Hz.

The spectra according to FIGS. 11 to 14 arise under the condition that the width of the dark resonance is less than the modulation frequency, meaning Δν<<νₘ. This circumstance is manifested by the fact that the individual peaks, the distance of which always measures 2ωₘ, are clearly separate from each other in the in-phase spectrum on FIG. 11. The right portion of the in-phase spectrum is magnified in the depiction according to FIG. 11A. The different individual graphs of this depiction correspond to varying deviations δν=ν_{HFS}−2ν_{R} of the current frequency of the radio frequency synthesizer 24 from the desired set frequency ν_{HFS} of the atomic transition between the ground states of the atoms located in the measurement cell 14. As demonstrated by an expanded system analysis, the introductory qualitative deliberations relating to the splitting of the dark resonances are also analogously correct as a function of Δν for the important case Δν<<νₘ. However, the line centroid of the in-phase signal (the in-phase spectrum is proportional to the absorption signal (˜χ″) of the CPT dark resonance) of the dark resonance is shifted by the frequency amount ±νₘ relative to the central frequency ω₀ (or ν₀) of the frequency generator 25.

The in-phase signal of the coupled dark resonances under the condition Δν<<νₘ is less suitable as a control signal for the frequency generator 25, since it (in addition to the undesired frequency offset) exhibits no point symmetry relative to its line centroid (see also FIG. 11).

By contrast, the frequency modulation spectrum of the dispersion signal (see FIG. 12) is well suited as a control signal for the tunable frequency generator 25 in the case of Δν<<νₘ. System analysis reveals that the central portion of the spectrum is point symmetrical relative to the line centroid, and hence can be drawn upon as the input signal for the controller 32. In addition, the line centroid (=zero position) corresponds with the frequency of the frequency generator 25.

With the switch S1 closed, the frequency of the frequency generator 25 is always stabilized to the frequency of the line centroid (=zero point) by the effect of the controller 32. The lock point corresponds to the point ν₀=0 on FIG. 12. Since the frequency value ν_{B}=C·B corresponds to the origin in this figure, the frequency of the generator 25 ν₀=ν_{B}=C·B (see also equation 5 and accompanying explanation) can be used directly for measuring the outer magnetic field B given a closed control loop.

In the simplest case, the servo unit or controller 32 consists of an analog (or digital) slave controller system, for example consisting of amplifying (P), integrating (I), and differentiating (D) units (PID controllers). Realization also takes place for an analog configured controller 32 via discrete electronic components, and for a digital controller via the software implementation of the corresponding computer operations (PID etc.) in a digital computer.

Both realization options (analog and digital) for the controller 32 share in common that the search for the lock point takes place via the simultaneous satisfaction of conditions
Amplitude=set value=0
Sign of the control flank inclination=positive

(Whether the sign is positive or negative depends on the control flank. On FIG. 12, the sign is positive.)

The signal on FIG. 12 is unambiguous in terms of the simultaneous satisfaction of both mentioned criteria. This means that, with the switch 1 closed, the frequency γ₀ of the generator 25 is automatically and unambiguously tuned to the point ν₀=ν_{B}=C·B (origin on FIG. 12). Therefore, frequency ν₀=ν_{B} automatically corresponds to the frequency splitting of the Zeeman sub-level (=splitting of dark resonances). As a result, measuring the frequency ν₀ or ν_{B} makes it possible to directly determine the outer magnetic field (to be measured).

As evident from both the introductory qualitative discussion and the aforementioned expanded system analysis (see also FIG. 12), detuning the microwave generator 24 does not influence the position of the line centroid of the signals according to FIGS. 11 and 12. The accuracy of magnetic field measurement, which takes place over the position of the line centroid, is hence not influenced by a microwave generator drift.

The maximum permissible range for microwave generator drift is not given by δν≦0.289 Δν_{CPT} (with Δν_{CPT}=Δν) when using the signal from FIG. 11, since the case Δν<<νₘ in the graphs on FIGS. 11 and 12 involves two independent signals (˜χ′ and ˜χ″), which are defined separately from each other by the equations 28 and 31. Therefore, the (weaker) condition δν≦0.5 Δν_{CPT} (applies in the range Δν<<νₘ.

However, the assumption posited at the outset that the control signal corresponds to the first derivation of the absorption signal applies for the case Δν>>νₘ. These deliberations advanced at the beginning can thus be incorporated directly. This behavior can also be envisioned by assuming that the modulation frequency is always diminishing. As a consequence, the two peaks on FIG. 11 of the absorption signal continuously edge closer together, until the first derivation of the absorption signal finally results in the borderline case. The varying signs yield a point symmetrical signal. In the end, both generated sidebands (given a variation in ν₀) simultaneously come to lie under the line profile of dark resonance (see also the pre-factor for term cos ωₘt in equation 39).

FIG. 13 (or FIG. 15B) depicts the signal portion belonging to the pre-factor of term cos(2ωₘt) (see also equation 39).

More in detail, FIG. 15A shows the frequency modulation spectrum in the case of ωₘ˜Δν for the control signal share of the coupled dark resonances belong to the term ˜sin 2ωₘt, whereas FIG. 15B depicts the corresponding spectrum of the correction control signal share belonging to the term cos 2ωₘt (see also equation 39). In both depictions, FIG. 15A and FIG. 15B, the detuning of the microwave generator 24 measures δν=0, 10, 25 or 50 Hz, so that four respective curves are shown.

As evident from these images according to FIG. 13 or FIG. 15B, the value of this signal at ω₀ is directly correlated from a functional standpoint with the detuning δν=ν_{HFS}2ν_{R} of the RF generator 24 in the locked-in state (switch S1 closed). As a result, this signal can be used in the magnetometer configuration to directly stabilize the frequency of the generator 24 to the value δν=0. A drift of the generator 24 that arises during magnetometer operation can always be compensated in this way. As a result of this measure, the steepness of the control flank always reaches its maximum value. The operating state of the control loop 18 is continuously optimized, since the greatest sensitivity (greatest signal-to-noise ratio) is always reached.

In a technical realization of the magnetometer, this signal can be generated via the synchronous demodulation of the signal of equation 39 in the lock-in amplifier 20 in conjunction with the frequency multiplier 41 (see FIG. 7). The signal component of FIG. 13 is finally obtained at the output of the controller 42 for the case Δν<<νₘ, while the signal component of FIG. 15B is obtained for the case Δν<≈νₘ.

In order to complete this correction control loop 43 of the generator 24, the lock-in amplifier 20 is connected in series to the additional servo loop or controller 42, which controls the generator 24 for purposes of frequency correction, and based on the amplitude (ν_{R})=max (see FIG. 13) (ω_{R}=2πν_{R}).

The fact that the magnetic field measurement ν₀ and detuning of the generator 24 are decoupled makes it possible to operate this correction control loop 43 with a large time constant. This enables the simultaneous operation of both control loops 18, 43.

These two control loops 18, 43 allow the magnetometer to operate without any additional recalibration. The correct lock point of the signal on FIG. 12 is always simultaneously assumed for the magnetic field measurement. Owing to the permanent post-correction of the frequency ω_{R} or ν_{R}, the magnetometer also always operates with the maximum achievable signal-to-noise ratio.

The validity of deliberations regarding the advantages of coupling dark resonances via a multichromatic laser field is established for any modulation frequencies νₘ desired (or for any Δν/νₘ correlations desired). In order to illustrate this, the frequency modulation spectra important for magnetometer operation are indicated for the νₘ=Δν mode. The parameters selected in the following examples are the same as those on FIGS. 11 to 14.

As evident from the graphs of the dispersion signal on FIG. 15A, a suitable control signal results even in this regime, ensuring an unambiguous locking-in of the generator 25. The tolerance range relative to a detuning of the RF synthesizer 24 of δν≈½Δν corresponds roughly to the tolerance range valid for Δν<<νₘ. In like manner, an unambiguous signal for the correction control loop can be derived from the frequency modulation spectrum of the 2^{nd} harmonic component (see also FIG. 13).

The principles expounded above are generally valid, and hence independent of whether digital or analog components are used. However, it should be borne in mind when using digital components that the corresponding connecting lines of the block diagram according to FIG. 7 must be viewed as data lines. Many of the units depicted on FIG. 7 are in this case implemented with software in the program of a digital computer. The generator 25 can take the form of a so-called digital-data-synthesis generator (DDS generator), which is controlled by digital data words. The frequency ω₀ is then coded by a data word.

Given a digital realization of the generator 25 by means of a DDS generator with servo, the frequency counter 35 can also be omitted, since the frequency can be directly gleaned from the corresponding data word at the input of the “generator” 25. The data stream can now be directly converted into a magnetic field variable by means of a (digital) microprocessor. However, let it still be pointed out that this DDS generator 25 should derive its clock from the OCXO time base 23, so as to avoid stability and accuracy losses.

1. A method for measuring magnetic fields (B) based on the Zeeman effect using dark resonances, wherein quantum systems, e.g., atoms or molecules, of a measurement medium are irradiated with electromagnetic radiation at varying frequencies in a measurement cell (14) and excited during frequency tuning, thereby yielding a frequency splitting with a frequency shift (ν_{B}) owing to the Zeeman effect, wherein a diminished fluorescent radiation is brought about, with a diminished absorption or increased transmission at a resonance frequency, the dark resonance, which depends on the magnetic field, and which is determined via the frequency tuning, so as to determine the magnetic field therefrom, characterized in that several dark resonances are coupled through the use of a polychromatic electromagnetic radiation (12), so that a frequency detection dependent only on the frequency shift triggered by the magnetic field is conducted for purposes of magnetic field measurement.

2. The method according to claim 1, characterized in that the polychromatic electromagnetic radiation is generated via a multistage modulation of an electromagnetic ground radiation, in particular laser radiation.

3. The method according to claim 2, characterized in that a first high-frequency modulation frequency (ν_{mod1}) essentially equal to the frequency (ν_{HFS}) of the splitting of the ground state of the atoms in the measurement medium is generated, with which the electromagnetic ground radiation is modulated with the generation of a sideband structure, and which on its part is modulated with a second modulation signal (ν_{mod2}) that is low-frequency relative thereto.

4. The method according to claim 3, characterized in that the first modulation frequency (ν_{mod1}) is fixedly set, and the second modulation frequency (ν_{mod2}) is tuned to the resonance state.

5. The method according to claim 3, characterized in that the low-frequency second modulation signal is for its part also modulated to facilitate its tuning to the resonance state.

6. A device for measuring magnetic fields based on the Zeeman effect, by means of dark resonance, with a measurement cell (14) that is exposed to the magnetic field (B) to be measured and contains atoms of a measurement medium in a buffer gas, a radiation source (11) being provided for the excitement thereof via irradiation, said radiation source connected with a modulation frequency generator and emitting an electromagnetic radiation with varying frequencies, and with a frequency detector (17) with a control loop (18) downstream from the measurement cell (14) for tuning the frequency to a dark resonance resonance frequency, characterized in that at least one modulator (22) for modulating a comparatively high first modulation frequency with a lower second modulation frequency with the generation of a double sideband structure is arranged downstream the modulation frequency generator (24), so that the electromagnetic radiation (12) modulated therewith provides for a coupling of several dark states, in which essentially only one frequency corresponding to the magnetic field-independent frequency shift is detected.

7. The device according to claim 6, characterized in that the modulation frequency generator (24) is set to a fixed frequency essentially equal to the frequency
$$\frac{1}{4} ( {v}_{+ 2 ges} + {v}_{- 2 ges} ) \approx \frac{1}{2} {v}_{HFS}$$
of the splitting of the ground state of the atoms of the measurement medium.

8. The device according to claim 6, characterized in that another control loop (43) is provided with a lock-in amplifier (20) which receives a mixed frequency from a frequency converter (41), and the output signal of which is routed to the modulation frequency generator (24) via a servo loop (42).

9. The device according to claim 7, characterized in that a high-frequency oscillator (23) is allocated to the modulation frequency generator (24) as the time base.

10. The device according to claim 9, characterized in that the high-frequency oscillator (23) is a quartz oscillator.

11. The device according to claim 6, characterized in that the modulator (22), which modulates the first modulation frequency with the lower, second modulation frequency, is a ring mixer.

12. The device according to claim 6, characterized in that a tunable frequency generator or voltage/frequency converter (25) that receives a voltage depending on the measurement signal of the frequency detector (17) is provided to generate the lower, second modulation frequency.

13. The device according to claim 12, characterized in that the frequency detector (17) comprises a lock-in amplifier (18), the output of which supplies the input voltage to the frequency generator or voltage/frequency converter (25) by way of a servo loop (32).

14. The device according to claim 13, characterized in that the input of the frequency generator or voltage/frequency converter (25) is selectively connectable to the output of a ramp generator (37).

15. The device according to claim 6, characterized in that the radiation source (11) is comprised of a VCSEL laser.

16. The device according to claim 15, characterized in that a temperature-stabilization loop (31) is allocated to the VCSEL laser.

17. The device according to claim 6, characterized in that the modulation signal is supplied to the radiation source (11) by way of an attenuator (26).

18. The device according to claim 6, characterized in that the modulation frequency generator (24) generates a frequency in a range of up to several GHz, in particular 3.4 GHz, and the lower modulation frequency measures up to several MHz.
